(19) United States
(12) Patent Application Publication
(10) Pub. No.: US 2025/0157542 A1
(43) Pub. Date: May 15, 2025

(54) NON-VOLATILE MEMORY DEVICE AND PROGRAMMING METHOD

(71) Applicant: Samsung Electronics Co., Ltd., Suwon-si (KR)

(72) Inventors: Dae Sik HAM, Suwon-si (KR); ByeongChan KO, Suwon-si (KR); Sanghun KIM, Suwon-si (KR)

(73) Assignee: Samsung Electronics Co., Ltd., Suwon-si (KR)

(21) Appl. No.: 18/810,861

(22) Filed: Aug. 21, 2024

(30) Foreign Application Priority Data
Nov. 9, 2023 (KR) 10-2023-0154407

(51) Int. Cl. G11C 16/10; G11C 16/04; G11C 16/08; G11C 16/34; H10B 43/27; H10B 43/35

(52) U.S. Cl. CPC G11C 16/10; G11C 16/0483; G11C 16/08; G11C 16/3459; H10B 43/27; H10B 43/35

(57) ABSTRACT

A method of programming a non-volatile memory device which includes a first cell string and a second cell string connected to a same bit line and sharing a first ground selection line, and a third cell string and a fourth cell string connected to the same bit line and sharing a second ground selection line, includes performing a ground separate initial precharge operation, in which a first voltage is applied to the first ground selection line and a second voltage is applied to the second ground selection line, based on the first cell string being selected as a selected cell string, performing a program voltage applying operation in which a program voltage is applied to a word line selected as a selected word line from among a plurality of word lines, and performing a verify operation in which a verify voltage is applied to the selected word line.

### CROSS-REFERENCE TO RELATED APPLICATIONS

This application claims priority under 35 U.S.C. § 119 to Korean Patent Application No. 10-2023-0154407 filed on Nov. 9, 2023, in the Korean Intellectual Property Office, the disclosures of which are incorporated by reference herein in their entireties.

### BACKGROUND

Example embodiments of the present inventive concepts described herein relate to non-volatile memory devices, and more particularly, relate to programming methods for reducing, minimizing, or preventing data damage and non-volatile memory devices configured to perform the same.

A semiconductor memory is classified as a volatile memory, which loses data stored therein when a power is turned off, such as a static random access memory (SRAM) or a dynamic random access memory (DRAM) or a nonvolatile memory, which retains data stored therein even when a power is turned off, such as a flash memory, a phase-change RAM (PRAM), a magnetic RAM (MRAM), a resistive RAM (RRAM), or a ferroelectric RAM (FRAM).

### SUMMARY

Some example embodiments of the present inventive concepts provide a programming method for preventing data from being damaged while a program operation is performed, or reducing or minimizing such damage.

Some example embodiments of the present inventive concepts provide a non-volatile memory device performing a program operation for preventing data from being damaged while the program operation is performed, or reducing or minimizing such damage.

According to some example embodiments, a method of programming a non-volatile memory device which includes a first cell string and a second cell string connected to the same bit line and sharing a first ground selection line, and a third cell string and a fourth cell string connected to the bit line and sharing a second ground selection line may include performing a ground separate initial precharge operation, in which a first voltage is applied to the first ground selection line and a second voltage is applied to the second ground selection line, based on the first cell string being selected as a selected cell string, performing a program voltage applying operation in which a program voltage is applied to a word line selected as a selected word line from among a plurality of word lines, performing a verify operation in which a verify voltage is applied to the selected word line, and performing a recovery operation in which a recovery voltage is applied to the plurality of word lines connected to the first to fourth cell strings.

According to some example embodiments, a method of programming a non-volatile memory device which includes a plurality of cell strings connected to a same bit line may include selecting one cell string of the plurality of cell strings as a selected cell string, selecting one word line of a plurality of word lines connected to the selected cell string as a selected word line, and performing a program operation on memory cells connected to the selected word line. The performing of the program operation may include performing a ground separate initial precharge operation based on applying a first voltage to a first ground selection line connected to the selected cell string and applying a second voltage to a second ground selection line connected to an unselected cell string among the plurality of cell strings.

According to some example embodiments, a non-volatile memory device may include a plurality of memory blocks. Each memory block of the plurality of memory blocks may include a first cell string and a second cell string connected to a same bit line and sharing a first ground selection line, and a third cell string and a fourth cell string connected to the same bit line and sharing a second ground selection line. The non-volatile memory device may be configured to perform a precharge operation on a cell string of the first to fourth cell strings, the precharge operation including independently controlling a first ground selection voltage applied to the first ground selection line and a second ground selection voltage applied to the second ground selection line.

### BRIEF DESCRIPTION OF THE DRAWINGS

The above and other objects and features of the present inventive concepts will become apparent by describing in detail some example embodiments thereof with reference to the accompanying drawings.

FIG. 1 is a block diagram illustrating a non-volatile memory device according to some example embodiments of the present inventive concepts.

FIG. 2 is a circuit diagram illustrating an example of one memory block among memory blocks of FIG. 1 according to some example embodiments of the present inventive concepts.

FIG. 3 is a diagram illustrating a program operation on cell strings connected to a first bit line of FIG. 2 according to some example embodiments of the present inventive concepts.

FIG. 4 is a perspective view illustrating a structure of a portion of a memory block of FIG. 1 according to some example embodiments of the present inventive concepts.

FIG. 5 is a diagram illustrating an example in which a non-volatile memory device of FIG. 1 performs a program operation in response to a program command according to some example embodiments of the present inventive concepts.

FIG. 6 is a diagram illustrating an example in which a non-volatile memory device of FIG. 1 performs program loops of a program operation in response to a program command according to some example embodiments of the present inventive concepts.

FIG. 7 is a diagram illustrating an example of operations constituting each program loop of FIG. 6 according to some example embodiments of the present inventive concepts.

FIGS. 8, 9, 10, and 11 illustrate an example in which memory cells connected to a fifth word line are programmed according to some example embodiments of the present inventive concepts.

FIG. 12 illustrates an example of voltages applied to a string selection line, a word line, and a ground selection line when a program operation is performed according to some example embodiments of the present inventive concepts.

FIG. 13 illustrates channel voltage distributions of a first cell string and a second cell string at each point in time of FIG. 12 according to some example embodiments of the present inventive concepts.

FIG. 14 is a diagram illustrating an example of a programming method according to some example embodiments of the present inventive concepts.

FIG. 15 is a diagram illustrating an example of a programming method of operation S230 of FIG. 14 according to some example embodiments of the present inventive concepts.

FIG. 16 is a flowchart illustrating some example embodiments of a ground separate initial precharge of FIG. 14 according to some example embodiments of the present inventive concepts.

FIG. 17 is a graph illustrating a ground separate initial precharge operation of FIG. 16 according to some example embodiments of the present inventive concepts.

FIG. 18 is a flowchart illustrating some example embodiments of a ground separate initial precharge of FIG. 14 according to some example embodiments of the present inventive concepts.

FIG. 19 is a graph illustrating a ground separate initial precharge operation of FIG. 18 according to some example embodiments of the present inventive concepts.

FIG. 20 is a diagram illustrating how a hot carrier injection effect is prevented when a ground separate initial precharge operation is performed according to some example embodiments of the present inventive concepts.

FIG. 21 is a block diagram illustrating a non-volatile memory device according to some example embodiments of the present inventive concepts.

FIG. 22 is a diagram illustrating an example of a ground selection voltage control circuit of FIG. 21 according to some example embodiments of the present inventive concepts.

FIG. 23 is a diagram for describing an example of an operation method of a ground selection voltage control circuit of FIG. 22 according to some example embodiments of the present inventive concepts.

FIG. 24 is a diagram for describing an example of an operation method of a ground selection voltage control circuit of FIG. 22 according to some example embodiments of the present inventive concepts.

FIG. 25 is a diagram illustrating an example of a ground selection voltage control circuit of FIG. 21 according to some example embodiments of the present inventive concepts.

FIG. 26 is a diagram for describing an example of an operation method of a ground selection voltage control circuit of FIG. 25 according to some example embodiments of the present inventive concepts.

FIG. 27 is a diagram for describing an example of an operation method of a ground selection voltage control circuit of FIG. 25 according to some example embodiments of the present inventive concepts.

FIG. 28 is a diagram illustrating an example of a memory block according to some example embodiments of the present inventive concepts.

FIGS. 29 and 30 illustrate an example in which memory cells connected to a fifth word line of FIG. 28 are programmed according to some example embodiments of the present inventive concepts.

FIG. 31 is a diagram illustrating a storage device according to some example embodiments of the present inventive concepts.

### DETAILED DESCRIPTION

Below, some example embodiments of the present inventive concepts will be described in detail and clearly to such an extent that an ordinary one in the art easily carries out the present inventive concepts.

The same reference numerals are used for the same components in the drawings, and redundant descriptions thereof are omitted.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, an element that is “on” another element may be above, beneath, or horizontally next to (e.g., horizontally adjacent to) the other element and is not necessarily above an upper side of the other element based on a gravitational direction.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

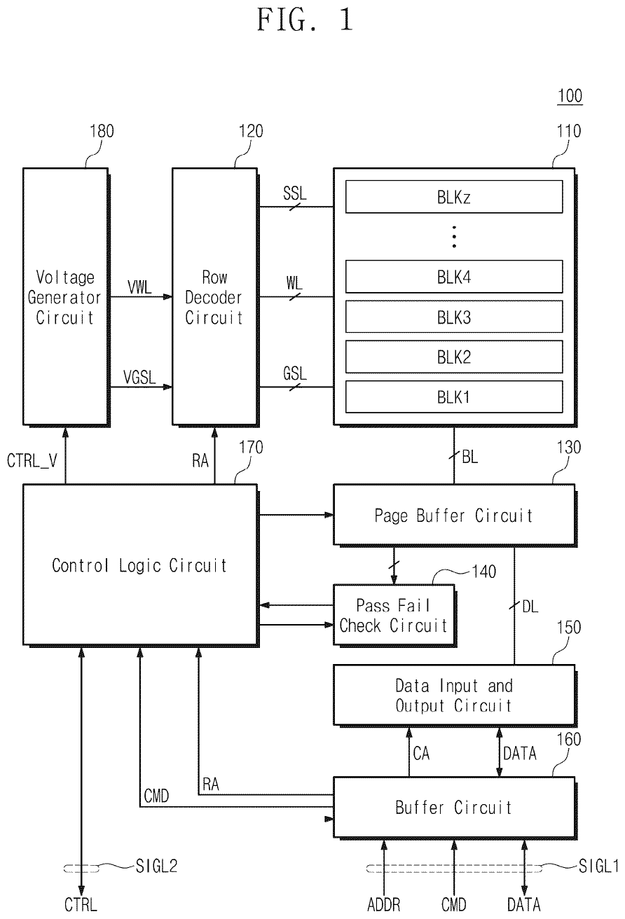

FIG. 1 is a block diagram illustrating a non-volatile memory device according to some example embodiments of the present inventive concepts. Referring to FIG. 1, a non-volatile memory device 100 may include a memory cell array 110, a row decoder circuit 120, a page buffer circuit 130, a data input and output circuit 150, a buffer circuit 160, a control logic circuit 170, and a voltage generator circuit 180.

The memory cell array 110 includes a plurality of memory blocks BLK1 to BLKz. Each of the memory blocks BLK1 to BLKz includes a plurality of memory cells, “z” being any positive integer. Each of the memory blocks BLK1 to BLKz may be connected to the row decoder circuit 120 through at least one ground selection line GSL, word lines WL, and at least one string selection line SSL. Some of the word lines WL may be used as dummy word lines. Each of the memory blocks BLK1 to BLKz may be connected to the page buffer circuit 130 through a plurality of bit lines BL.

In some example embodiments, each of the plurality of memory blocks BLK1 to BLKz may correspond to a unit of the erase operation. Memory cells belonging to each memory block may be erased at the same time. As another example, each of the memory blocks BLK1 to BLKz may be divided into a plurality of sub-blocks. Each of the plurality of sub-blocks may correspond to a unit of the erase operation.

The row decoder circuit 120 is connected to the memory cell array 110 through the ground selection lines GSL, the word lines WL, and the string selection lines SSL. The row decoder circuit 120 operates under control of the control logic circuit 170.

The row decoder circuit 120 may decode a row address RA received from the buffer circuit 160 and may control voltages to be applied to the string selection lines SSL, the word lines WL, and ground selection lines GSL based on the decoded row address.

The page buffer circuit 130 is connected to the memory cell array 110 through the bit lines BL. The page buffer circuit 130 is connected to the data input and output circuit 150 through a plurality of data lines DL. The page buffer circuit 130 operates under control of the control logic circuit 170.

In the program operation, the page buffer circuit 130 may store data to be written in memory cells. The page buffer circuit 130 may apply voltages to the bit lines BL based on the stored data.

In the read operation or in the verify read operation which is performed in the program operation or the erase operation, the page buffer circuit 130 may sense voltages of the bit lines BL and may store a result of the sensing.

In the verify read operation associated with the program operation or the erase operation, the pass fail check circuit 140 may verify the sensing result of the page buffer circuit 130. The pass fail check circuit 140 may determine a pass or a fail from a result of the verify read operation (e.g., a program verify read operation or an erase verify read operation) stored in the page buffer circuit 130.

The data input and output circuit 150 is connected to the page buffer circuit 130 through the plurality of data lines DL. The data input and output circuit 150 may receive a column address CA from the buffer circuit 160. The data input and output circuit 150 may output the data read by the page buffer circuit 130 to the buffer circuit 160 depending on the column address CA. The data input and output circuit 150 may transfer the data received from the buffer circuit 160 to the page buffer circuit 130 depending the column address CA.

Through first signal lines SIGL1, the buffer circuit 160 may receive a command CMD and an address ADDR from an external device and may exchange data “DATA” with the external device. The buffer circuit 160 may operate under control of the control logic circuit 170. The buffer circuit 160 may transfer the command CMD to the control logic circuit 170. The buffer circuit 160 may transfer the row address RA among the address ADDR to the row decoder circuit 120 and may transfer the column address CA among the address ADDR to the data input and output circuit 150. The buffer circuit 160 may exchange the data “DATA” with the data input and output circuit 150.

The control logic circuit 170 may exchange a control signal CTRL with the external device through second signal lines SIGL2. The control logic circuit 170 may allow the buffer circuit 160 to route the address ADDR and the data “DATA” to the control logic circuit 170, the row decoder circuit 120, and the data input and output circuit 150. The control logic circuit 170 may decode the command CMD received from the buffer circuit 160 and may control the non-volatile memory device 100 depending on the decoded command.

The voltage generator circuit 180 may generate various kinds of voltages for performing the program, read, and erase operations based on a voltage control signal CTRL_V from the control logic circuit 170. For example, the voltage generator circuit 180 may generate a program voltage, a read voltage, a program verify voltage, an erase voltage, etc. as a word line voltage VWL.

In some example embodiments, the voltage generator circuit 180 may be configured to control a ground selection voltage VGSL to be applied to the ground selection lines GSL in the execution of the program operation. How the voltage generator circuit 180 controls the ground selection voltage VGSL will be described in detail later.

In some example embodiments, the non-volatile memory device 100 may be manufactured in a bonding method. The memory cell array 110 may be manufactured at a first wafer, and the row decoder circuit 120, the page buffer circuit 130, the pass fail check circuit 140, the data input and output circuit 150, the buffer circuit 160, the control logic circuit 170, and the voltage generator circuit 180 may be manufactured at a second wafer. The non-volatile memory device 100 may be implemented by coupling the first wafer and the second wafer such that an upper surface of the first wafer and an upper surface of the second wafer face each other.

As another example, the non-volatile memory device 100 may be manufactured in a cell over peri (COP) method. A peripheral circuit including the row decoder circuit 120, the page buffer circuit 130, the pass fail check circuit 140, the data input and output circuit 150, the buffer circuit 160, and the control logic circuit 170, and the voltage generator circuit 180 may be implemented on a substrate. The memory cell array 110 may be implemented over the peripheral circuit. The peripheral circuit and the memory cell array 110 may be connected by using through vias.

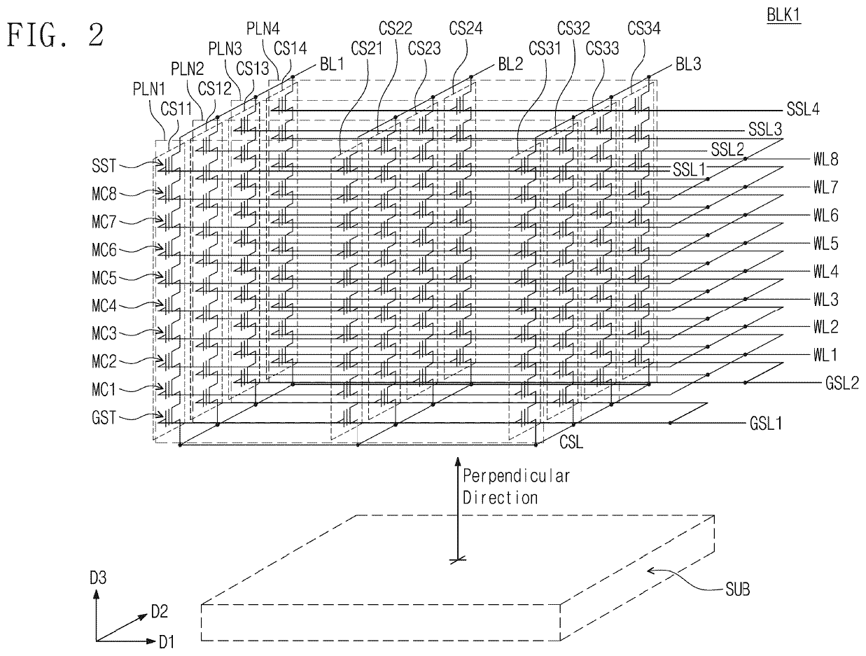

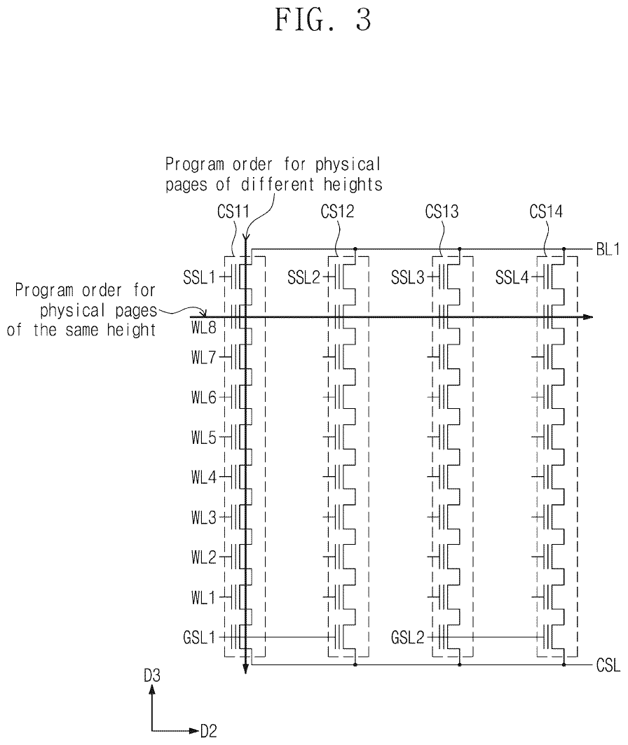

FIG. 2 is a circuit diagram illustrating an example of one memory block among memory blocks of FIG. 1 according to some example embodiments of the present inventive concepts. FIG. 3 is a diagram illustrating a program operation on cell strings connected to a first bit line of FIG. 2 according to some example embodiments of the present inventive concepts.

Referring to FIG. 2, a plurality of cell strings CS11 to CS14, CS21 to CS24, and CS31 to CS34 may be arranged on a substrate SUB in rows and columns. Each row may extend along a first direction D1. Each column may extend along a second direction D2. However, the present inventive concepts are not limited thereto. For example, more cell strings may be disposed along each row and each column.

Each of the cell strings CS11 to CS14, CS21 to CS24, and CS31 to CS34 may include memory cells MC1 to MC8 respectively connected to a plurality of word lines WL1 to WL8. Each of the cell strings CS11 to CS14, CS21 to CS24, and CS31 to CS34 may further include a string selection transistor SST connected to a string selection line and a ground selection transistor GST connected to a ground selection line.

Cell strings disposed at the same row along the first direction D1 may constitute one plane. For example, a first plane PLN1 may include the first cell strings CS11, CS21, and CS31 disposed along the first row, a second plane PLN2 may include the second cell strings CS12, CS22, and CS32 disposed along the second row, a third plane PLN3 may include the third cell strings CS13, CS23, and CS33 disposed along the third row, and a fourth plane PLN4 may include the fourth cell strings CS14, CS24, and CS34 disposed along the fourth row.

The first to fourth planes PLN1 to PLN4 may be respectively connected to different string selection lines. For example, the first cell strings CS11, CS21, and CS31 of the first plane PLN1 may be connected to a first string selection line SSL1. The second cell strings CS12, CS22, and CS32 of the second plane PLN2 may be connected to a second string selection line SSL2. The third cell strings CS13, CS23, and CS33 of the third plane PLN3 may be connected to a third string selection line SSL3. The fourth cell strings CS14, CS24, and CS34 of the fourth plane PLN4 may be connected to a fourth string selection line SSL4.

The first to fourth string selection lines SSL1 to SSL4 may be electrically separated from each other. For example, the first to fourth cell strings CS11 to CS34 may be independently selected based on voltages applied to the first to fourth string selection lines SSL1 to SSL4 separated from each other.

At least two of the first to fourth planes PLN1 to PLN4 may be connected to the same ground selection line.

For example, the first and second planes PLN1 and PLN2 may be connected in common to a first ground selection line GSL1, and the first cell strings CS11, CS21, and CS31 of the first plane PLN1 and the second cell strings CS12, CS22, and CS32 of the second plane PLN2 may be simultaneously controlled based on a voltage applied to the first ground selection line GSL1.

For example, the third and fourth planes PLN3 and PLN4 may be connected in common to a second ground selection line GSL2, and the third cell strings CS13, CS23, and CS33 of the third plane PLN3 and the fourth cell strings CS14, CS24, and CS34 of the fourth plane PLN4 may be simultaneously controlled based on a voltage applied to the second ground selection line GSL2.

In some example embodiments, the first and second ground selection lines GSL1 and GSL2 may be electrically separated. A first ground selection voltage applied to the first ground selection line GSL1 and a second ground selection voltage applied to the second ground selection line GSL2 may be controlled by the voltage generator circuit 180 of FIG. 1.

The plurality of cell strings CS11 to CS14, CS21 to CS24, and CS31 to CS34 may be connected in common to a common source line CSL formed on (or in) the substrate SUB. In FIG. 2, a location of the substrate SUB is depicted as an example for better understanding of the structure of the memory block BLK1.

In each cell string, the ground selection transistor GST, the memory cells MC1 to MC8, and the string selection transistor SST may be connected in series in a direction perpendicular to the substrate SUB, for example, a third direction D3 and may be sequentially stacked in the direction perpendicular to the substrate SUB. In each cell string, at least one of the memory cells MC1 to MC8 may be used as a dummy memory cell. The dummy memory cell may not be programmed (e.g., may be program-inhibited) or may be programmed to be different from that of the remaining memory cells among the memory cells MC1 to MC8.

In each of the first to fourth planes PLN1 to PLN4, memory cells located at the same height and associated with one string selection line (e.g., one of the first to fourth string selection lines SSL1 to SSL4) may constitute one physical page. Memory cells belonging to one physical page may be connected to one word line. For example, the eighth memory cells MC8 of the first cell strings CS11, CS21, and CS31 connected to the first string selection line SSL1 may constitute one physical page.

The program operation may be performed in units of physical page. When the program operation is performed, a string selection line (e.g., the first string selection line SSL1) corresponding to cell strings (e.g., the first cell strings CS11, CS21, and CS31) of a physical page targeted for the program operation from among the first to fourth string selection lines SSL1 to SSL4 may be selected, and the remaining string selection lines may not be selected.

Referring to FIGS. 2 and 3 together, the program operation on different physical pages arranged at the same height may progress along the second direction D2. For example, the first to fourth cell strings CS11 to CS14 connected to a first bit line BL1 may be sequentially programmed along the second direction D2.

After the program operation is performed with respect to all the physical pages of the same height, the program operation may be performed with respect to physical pages immediately underlying. For example, after memory cells connected to the eighth word line WL8 from among the memory cells of the first to fourth cell strings CS11 to CS14 are programmed, memory cells connected to the seventh word line WL7 from among the memory cells of the first to fourth cell strings CS11 to CS14 may be programmed.

The program operations on physical pages of different heights may be sequentially performed in the top-down direction (e.g., in a direction facing away from the third direction D3), that is, from the uppermost physical pages (e.g., physical pages connected to the eighth word line WL8) to the lowermost physical pages (e.g., physical pages connected to the first word line WL1).

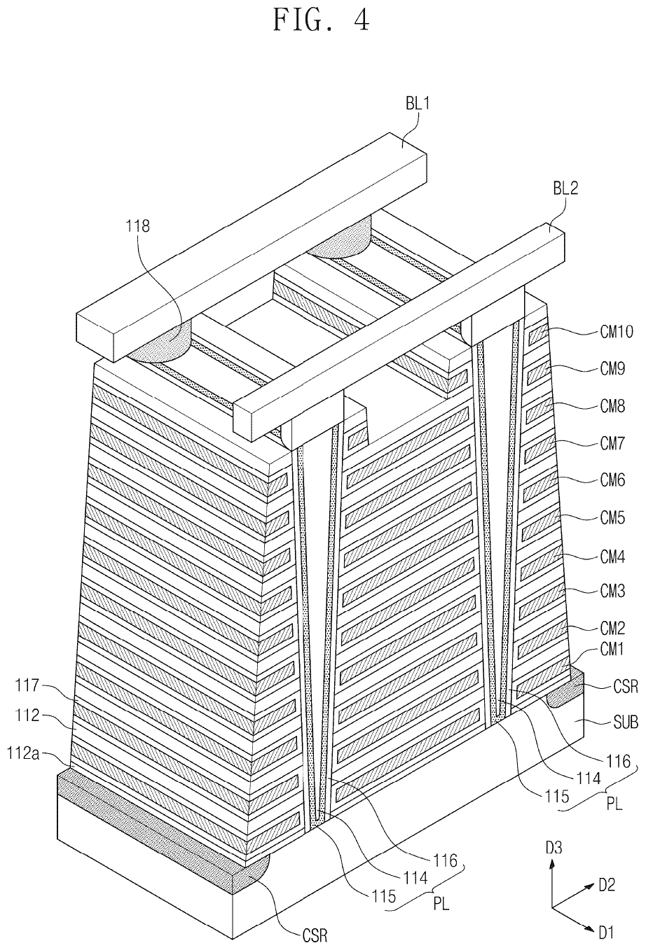

FIG. 4 is a perspective view illustrating a structure of a portion of a memory block of FIG. 1 according to some example embodiments of the present inventive concepts. Referring to FIGS. 1, 2, and 4, a portion of first and second planes connected to the first ground selection line GSL1 is illustrated.

Common source regions CSR may extend along the first direction D1 and may be spaced from each other along the second direction D2.

The common source regions CSR may be connected in common to form the common source line CSL. In some example embodiments, the substrate SUB may include a P-type semiconductor material. The common source regions CSR may include an N-type semiconductor material. For example, a conductive material for increasing the conductivity of the common source line CSL may be disposed on the common source regions CSR.

Between the common source regions CSR, insulating layers 112 and 112a are sequentially stacked on the substrate SUB along the third direction D3 perpendicular to the substrate SUB. The insulating layers 112 and 112a may be stacked along the third direction D3 so as to be spaced from each other. In some example embodiments, the insulating layers 112 and 112a may include silicon oxide or silicon nitride. In some example embodiments, the thickness of the insulating layer 112a (e.g., the thicknesses of the insulating layer 112a in the third direction D3), which is in contact with the substrate SUB, from among the insulating layers 112 and 112a may be thinner than the thicknesses of each of the remaining insulating layers 112 (e.g., the thickness of each insulating layer in the third direction D3).

Pillars PL may be disposed to be spaced from each other along the first direction D1 and the second direction D2 and may penetrate the insulating layers 112 and 112a along the third direction D3. In some example embodiments, the pillars PL may be in contact with the substrate SUB through the insulating layers 112 and 112a. Each of the pillars PL may include an inner material 114, a channel layer 115, and a first insulating layer 116.

The inner material 114 may include an insulating material or an air gap. The channel layer 115 may include a P-type semiconductor material or an intrinsic semiconductor material. The first insulating layer 116 may include one or more insulating layers (e.g., different insulating layers) such as a silicon oxide layer, a silicon nitride layer, and an aluminum oxide layer.

Between the common source regions CSR, second insulating layers 117 are provided on upper surfaces and lower surfaces of the insulating layers 112 and 112a and on exposed outer surfaces of the pillars PL. There may be removed the second insulating layer 117 provided on the upper surface of the uppermost insulating layer among the insulating layers 112 and 112a.

In each of the pillars PL, the first insulating layer 116 and the second insulating layer 117 may form an information storage layer when coupled adjacent to each other. For example, the first insulating layer 116 and the second insulating layer 117 may include oxide-nitride-oxide (ONO) or oxide-nitride-aluminum (ONA). The first insulating layer 116 and the second insulating layer 117 may form a tunneling insulating layer, a charge trap layer, and a blocking insulating layer.

Between the common source regions CSR and between and insulating layers 112 and 112a, conductive materials CM1 to CM10 are provided on exposed outer surfaces of the second insulating layers 117. The conductive materials CM1 to CM10 may include a metallic conductive material. Drains 118 are provided on the pillars PL. In some example embodiments, the drains 118 may include an N-type semiconductor material (e.g., silicon). In some example embodiments, the drains 118 may be in contact with the upper surfaces of the channel layers 115 of the pillars PL.

The first and second bit lines BL1 and BL2 which extend along the second direction D2 and are spaced from each other along the first direction D1 are provided on the drains 118. The first and second bit lines BL1 and BL2 are connected to the drains 118. In some example embodiments, the drains 118 and the first and second bit lines BL1 and BL2 may be connected through contact plugs. The first and second bit lines BL1 and BL2 may include metallic conductive materials.

The pillars PL form the cell strings CS11 to CS31 and CS12 and CS32 together with the first and second insulating layers 116 and 117 and the conductive materials CM1 to CM10. Each of the pillars PL forms a cell string together with the first and second insulating layers 116 and 117 and the conductive materials CM1 to CM10, which are adjacent thereto. The first conductive material CM1 may form the ground selection transistors GST together with the first and second insulating layers 116 and 117 and the channel layers 115, which are adjacent thereto. The first conductive material CM1 may extend along the first direction D1 to form the first ground selection line GSL1.

The second to ninth conductive materials CM2 to CM9 may respectively form the first to eighth memory cells MC1 to MC8 together with the first and second insulating layers 116 and 117 and the channel layers 115, which are adjacent thereto. The second to ninth conductive materials CM2 to CM9 may extend along the first direction D1 to form the first to eighth word lines WL1 to WL8, respectively.

However, the present inventive concepts are not limited to the example illustrated in FIG. 2. For example, each cell string may include a first string selection transistor and a second string selection transistor.

The tenth conductive materials CM10 may form the string selection transistor SST together with the first and second insulating layers 116 and 117 and the channel layers 115, which are adjacent thereto. The tenth conductive materials CM10 may extend in the first direction D1 to form the string selection lines SSL1 and SSL2.

As the first to tenth conductive materials CM1 to CM10 are stacked along the third direction D3, in each cell string, the ground selection transistor GST, the memory cells MC1 to MC8, and the string selection transistor SST may be stacked along the third direction D3.

In each of the pillars PL, as the channel layer 115 is shared by the first to tenth conductive materials CM1 to CM10, each cell string may be implemented such that the ground selection transistor GST, the memory cells MC1 to MC8, and the string selection transistor SST are serially connected along the third direction D3. For example, the shared channel layer 115 may form a vertical body.

As the first to ninth conductive materials CM1 to CM9 are connected in common, each of the first ground selection line GSL1 and the first to eighth word lines WL1 to WL8 may be regarded as being connected in common to the cell strings CS11 to CS31 and CS12 to CS32.

The memory block BLK1 is provided at a three-dimensional (3D) memory array. The 3D memory array is monolithically formed in one or more physical levels of arrays of memory cells MC having an active area disposed above a silicon substrate and a circuitry associated with the operation of those memory cells MC. The circuitry associated with the operation of the memory cells MC may be located above or within a substrate. The term “monolithic” means that layers of each level of the array are directly deposited on the layers of each underlying level of the 3D memory array.

In some example embodiments of the present inventive concepts, the 3D memory array includes vertical cell strings (or NAND strings) which are vertically oriented such that at least one memory cell is located over another memory cell. The at least one memory cell may include a charge trap layer. Each of the cell strings CS11 to CS14, CS21 to CS24, and CS31 to CS34 further includes at least one selection transistor located above the memory cells MC. The at least one selection transistor may have the same structure as the memory cells MC and may be formed uniformly with the memory cells MC.

The following patent documents, which are hereby incorporated by reference, describe suitable configurations for three-dimensional memory arrays, in which the three-dimensional memory array is configured as a plurality of levels, with word lines and/or bit lines shared between levels: U.S. Pat. Nos. 7,679,133; 8,553,466; 8,654,587; 8,559,235; and US Pat. Pub. No. 2011/0233648.

In FIGS. 2 and 4, the common source region CSR is described as being formed at a portion of the substrate SUB. However, the common source region CSR may be implemented in the form of a plate covering the substrate SUB.

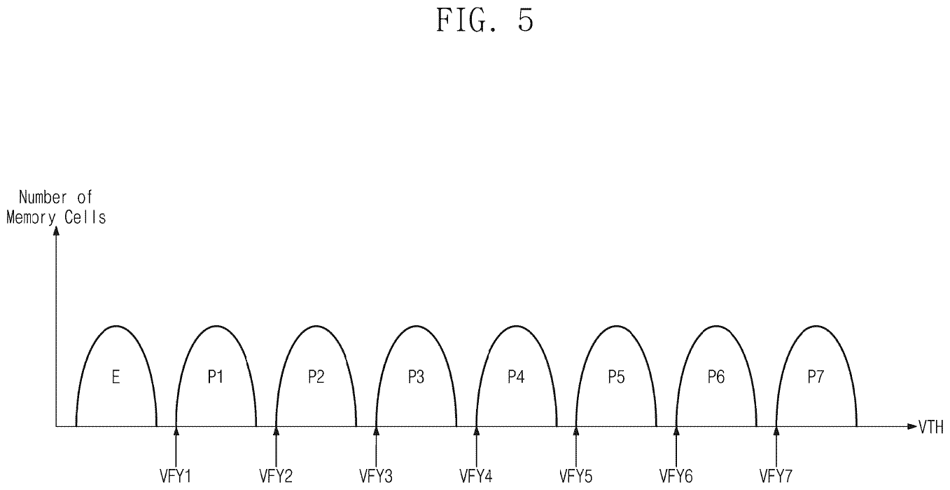

FIG. 5 is a diagram illustrating an example in which a non-volatile memory device of FIG. 1 performs a program operation in response to a program command according to some example embodiments of the present inventive concepts. In FIG. 5, the horizontal axis represents a threshold voltage VTH of a memory cell, and the vertical axis represents the number of memory cells.

Referring to FIGS. 1, 2, and 5, the non-volatile memory device 100 may program memory cells of an erase state “E” to first to seventh program states P1 to P7. For example, the memory cells of the non-volatile memory device 100 may be triple level cells (TLCs).

The non-volatile memory device 100 may verify program states of the memory cells by using first to seventh verify voltages VFY1 to VFY7.

In the program operation, each memory cell may maintain the erase state “E” or may be programmed to one of the first to seventh program states P1 to P7. The program state may indicate a range of threshold voltages of memory cells. For example, memory cells programmed to the first program state P1 may have threshold voltages included in a threshold voltage range marked by the first program state P1. Likewise, memory cells programmed to the second to seventh program states P2 to P7 may have threshold voltages included in threshold voltage ranges respectively marked by the second to seventh program states P2 to P7.

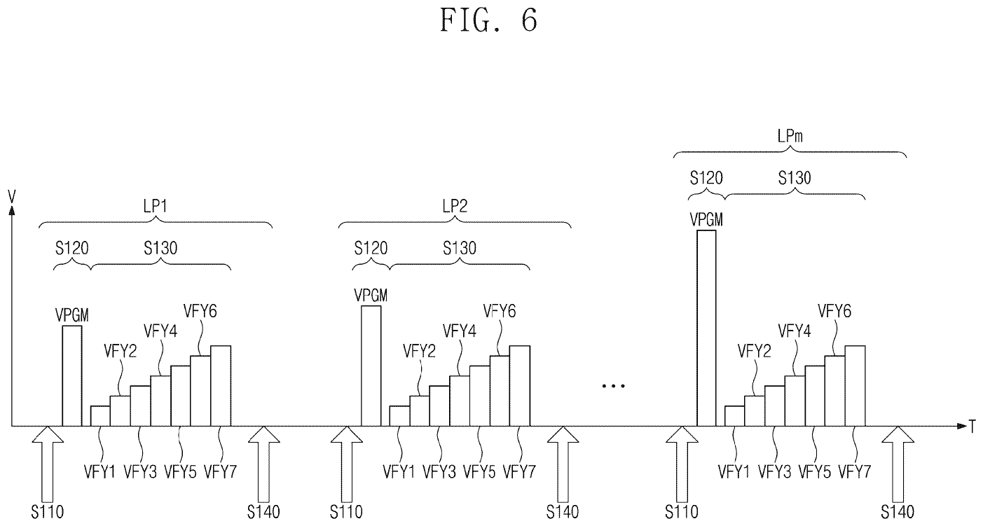

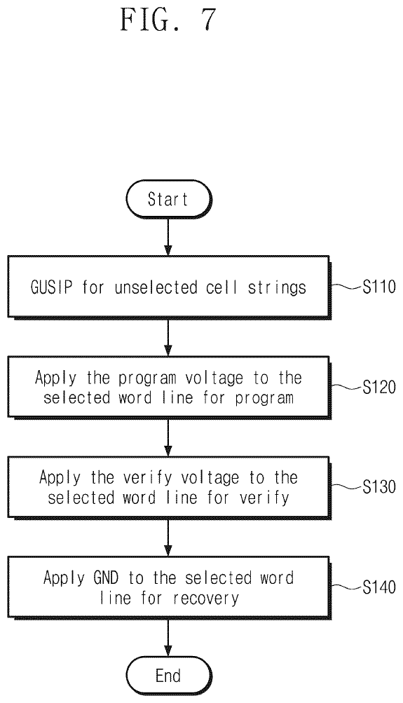

FIG. 6 is a diagram illustrating an example in which a non-volatile memory device of FIG. 1 performs program loops of a program operation in response to a program command according to some example embodiments of the present inventive concepts. FIG. 7 is a diagram illustrating an example of operations constituting each program loop of FIG. 6 according to some example embodiments of the present inventive concepts. It will be understood that the methods, operations, or the like shown in FIG. 6 and/or FIG. 7 may be implemented by a device according to any of the example embodiments (e.g., non-volatile memory device 100, non-volatile memory device 200, storage device 300, any combination thereof, or the like).

In FIG. 6, the horizontal axis represents a time “T”, and the vertical axis represents a voltage “V” applied to a selected word line.

Referring to FIGS. 1, 6, and 7, in the perform operation, the non-volatile memory device 100 may perform first to m-th program loops LP1 to LPm (m being a positive integer). For example, the non-volatile memory device 100 may perform the first to m-th program loops LP1 to LPm, the number of which is determined in advance.

Referring to FIGS. 6 and 7 together, in each of the first to m-th program loops LP1 to LPm, an initial precharge operation S110, a program voltage applying operation S120, a verify operation S130, and a recovery operation S140 may be performed.

In operation S110, the non-volatile memory device 100 may perform an initial precharge (GSL Unselected SSL Initial Precharge: GUSIP) operation on an unselected cell string through a ground selection transistor.

A selected cell string may mean a cell string including a memory cell targeted for the program operation. For example, a cell string may be selected (e.g., as a program target cell string) by applying a string selection voltage for turning on a string selection transistor to a string selection line.

The unselected cell string may mean a cell string including a memory cell not targeted for the program operation. For example, a cell string may not be selected by applying a string selection voltage for turning off a string selection transistor to a string selection line.

The non-volatile memory device 100 may perform initial precharging by applying a precharge voltage to a ground selection line connected to a ground selection transistor of an unselected cell string. The initial precharging may be for generating an initial boost-up voltage at a channel of an unselected cell string.

The initial boost-up voltage may be for improving a boost voltage which is formed at program-inhibited cell strings in the program operation. For example, the initial boost-up voltage may be for increasing a boost voltage of a channel such that program disturbance does not occur in the program operation. Herein, the program disturbance means that memory cells connected to unselected word lines adjacent to a selected word line are programmed depending on the program voltage.

When the initial precharging is performed, carriers may be injected into a channel of an unselected cell string through a ground selection transistor, and thus, the initial boost-up voltage may be formed at the channel of the unselected cell string.

In operation S120, the non-volatile memory device 100 may perform the program voltage applying operation in which the program voltage is selectively applied to a selected word line. The selected word line may mean a word line connected to the memory cell targeted for the program operation (e.g., a program target word line).

As a program voltage VPGM is applied to the selected word line, threshold voltages of the memory cells of the selected word line may increase. That is, the memory cells may be programmed.

In operation S130, the non-volatile memory device 100 may perform the verify operation on the programmed memory cell. For example, the non-volatile memory device 100 may perform the verify operation by applying the first to seventh verify voltages VFY1 to VFY7 to the programmed memory cell. The non-volatile memory device 100 may sequentially apply the first to seventh verify voltages VFY1 to VFY7 to the selected word line.

The non-volatile memory device 100 may perform a pass fail check (PFC) operation on results of the verify read stored in the page buffer circuit 130, that is, may determine whether each memory cell is programmed to a target program state among the first to seventh program states P1 to P7.

For example, when a threshold voltage of a memory cell to be programmed to the first program state P1 is smaller than the first verify voltage VFY1, the corresponding memory cell may be determined as the program fail. When a threshold voltage of a memory cell to be programmed to the first program state P1 is greater than the first verify voltage VFY1, the corresponding memory cell may be program-inhibited. Likewise, the non-volatile memory device 100 may program memory cells to the second to seventh program states P2 to P7 by using the second to seventh verify voltages VFY2 to VFY7.

As a program loop progresses (or is repeated), the level of the program voltage VPGM may increase. In an initial program loop such as the first program loop LP1, some of the first to seventh verify voltages VFY1 to VFY7, for example, some verify voltages, which are greater than the remaining verify voltages, such as the seventh verify voltage VFY7 may not be used. As a program loop progresses (or is repeated), a program state(s), which has a lower threshold voltage range(s) than the remaining program states, such as the first program state P1 may be program-passed prior to the remaining program states. A verify voltage (e.g., the first verify voltage VFY1), which corresponds to a program state first program-passed, from among the first to seventh verify voltages VFY1 to VFY7 may not be applied any longer.

In operation S140, the non-volatile memory device 100 may perform the recovery operation in which a recovery voltage is applied to word lines. For example, the recovery voltage may be a ground voltage. The recovery operation may be for setting a voltage condition for the purpose of executing a next program loop. To this end, the non-volatile memory device 100 may apply the ground voltage to a string selection line, word lines, and a ground selection line.

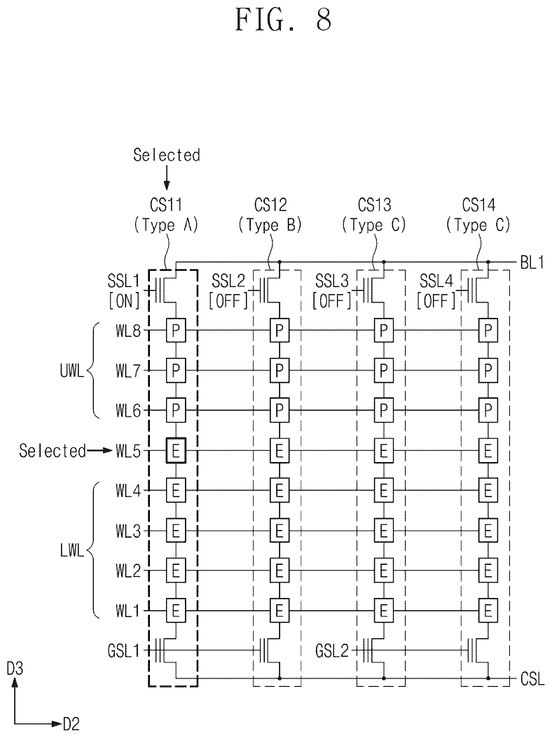

When the recovery operation is performed after the program voltage applying operation and the verify operation, a negative boost voltage may be formed at a channel of already programmed memory cells in some cell strings. Accordingly, hot electrons may be generated during the program voltage applying operation following the recovery operation and may have an influence on a program voltage of the already programmed memory cell. Below, an issue due to the hot electrons generated by the negative boost voltage will be described in detail with reference to FIGS. 8 to 13.

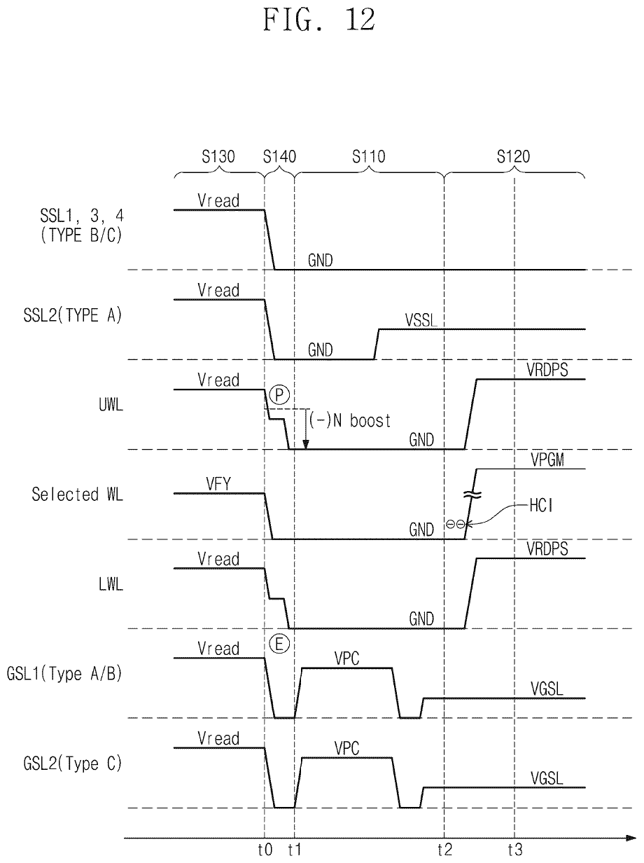

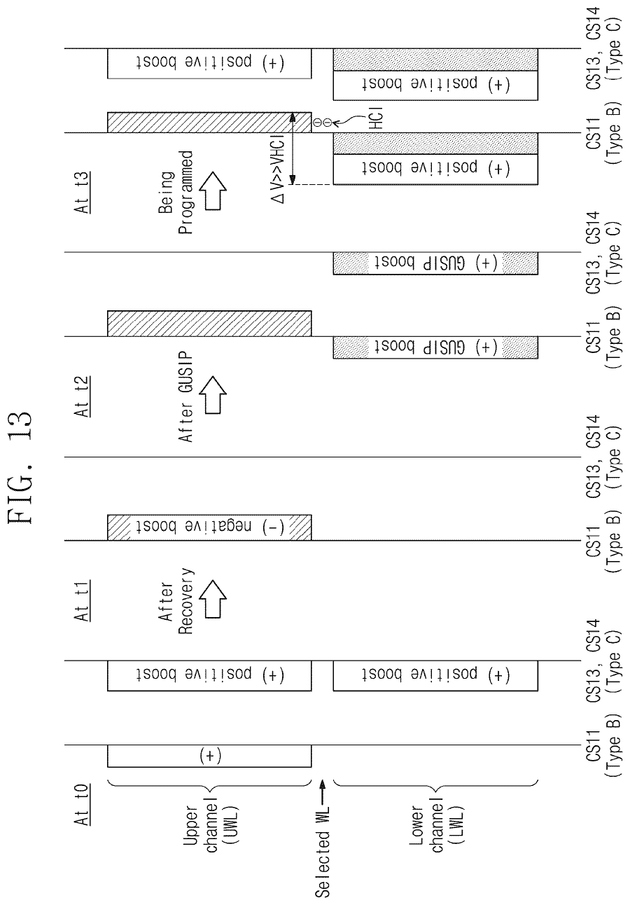

FIGS. 8, 9, 10, and 11 illustrate an example in which memory cells connected to a fifth word line are programmed according to some example embodiments of the present inventive concepts. FIG. 12 illustrates an example of voltages applied to a string selection line, a word line, and a ground selection line when a program operation is performed according to some example embodiments of the present inventive concepts. FIG. 13 illustrates channel voltage distributions of a first cell string and a second cell string at each point in time of FIG. 12 according to some example embodiments of the present inventive concepts.

In FIGS. 8 to 11, the first to fourth cell strings CS11 to CS14 connected to the first bit line BL1 of FIGS. 2 and 3 may be provided as an example. That is, components associated with the first bit line BL1 among the plurality of bit lines BL are only illustrated for convenience of description.

In the specification, a selected cell string targeted for the program operation is defined as a Type-A string; a cell string sharing the same ground selection line with the selected cell string is defined as a Type-B string; and, the remaining cell strings connected to a ground selection line different from that of the selected cell string are defined as a Type-C string. For example, the Type-A string shares a ground selection line with the Type-B string but does not share a ground selection line with the Type-C string.

In the specification, upper unselected word lines UWL mean word lines disposed to be closer to a string selection line than a selected word line from among unselected word lines, and lower unselected word lines LWL mean word lines disposed to be closer to a ground selection line than the selected word line from among the unselected word lines.

In the specification, an upper channel of a cell string may mean a channel of memory cells connected to the upper unselected word lines UWL, and a lower channel of a cell string may mean a channel of memory cells connected to the lower unselected word lines LWL.

According to the program order described with reference to FIG. 3, memory cells connected to the upper unselected word lines UWL may include already programmed memory cells. For example, memory cells connected to the upper unselected word lines UWL may be in one state among the erase state “E” and the first to seventh program states P1 to P7. Memory cells connected to the lower unselected word lines LWL are memory cells which are not yet programmed.

In FIGS. 8 to 11, the fifth word line WL5 is a selected word line, the sixth to eighth word lines WL6 to WL8 are the upper unselected word lines UWL, and the first to fourth word lines WL1 to WL4 are the lower unselected word lines LWL. That is, the memory cells connected to the sixth to eighth word lines WL6 to WL8 may be in a state of being programmed, and the memory cells connected to the first to fourth word lines WL1 to WL4 may be in a state of being not programmed.

Referring to FIG. 8, first, the program operation on a memory cell of the first cell string CS11, which is connected to the fifth word line WL5, may be performed.

In this case, the first cell string CS11 is the Type-A string, the second cell string CS12 sharing the first ground selection line GSL1 with the first cell string CS11 is the Type-B string, and the third and fourth cell strings CS13 and CS14 not sharing a ground selection line with the first cell string CS11 are the Type-C strings.

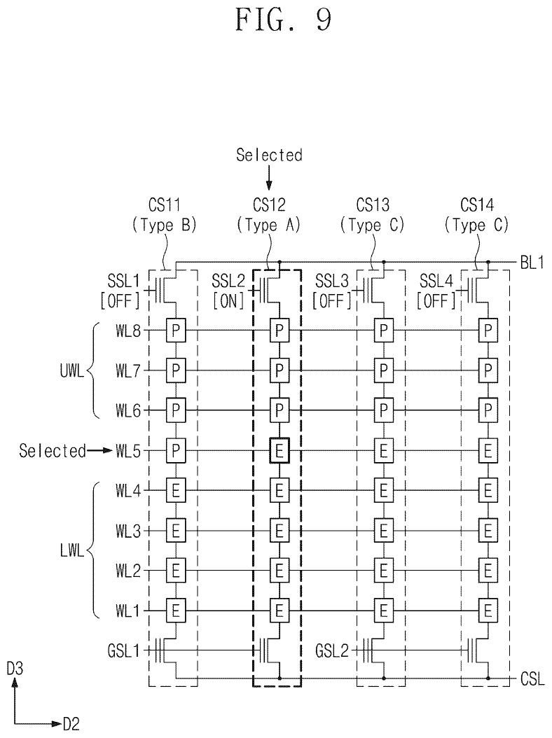

Referring to FIG. 9, after the program operation on the first cell string CS11 is completed, the program operation on a memory cell of the second cell string CS12, which is connected to the fifth word line WL5, may be performed.

In this case, the second cell string CS12 is the Type-A string, the first cell string CS11 sharing the first ground selection line GSL1 with the second cell string CS12 is the Type-B string, and the third and fourth cell strings CS13 and CS14 not sharing a ground selection line with the second cell string CS12 are the Type-C strings.

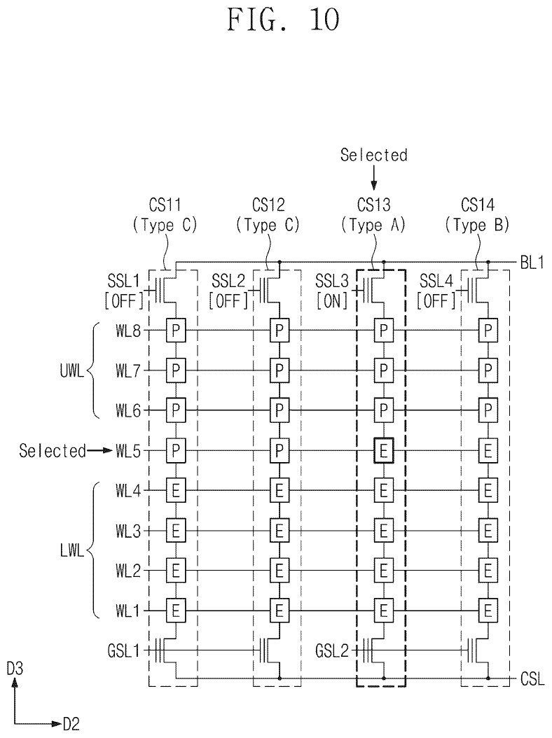

Referring to FIG. 10, after the program operation on the second cell string CS12 is completed, the program operation on a memory cell of the third cell string CS13, which is connected to the fifth word line WL5, may be performed.

In this case, the third cell string CS13 is the Type-A string, the fourth cell string CS14 sharing the second ground selection line GSL2 with the third cell string CS13 is the Type-B string, and the first and second cell strings CS11 and CS12 not sharing a ground selection line with the third cell string CS13 are the Type-C strings.

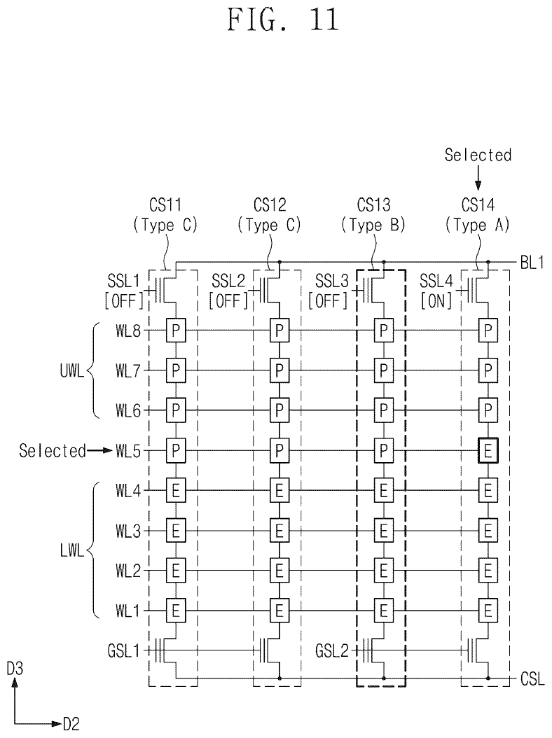

Referring to FIG. 11, after the program operation on the third cell string CS13 is completed, the program operation on a memory cell of the fourth cell string CS14, which is connected to the fifth word line WL5, may be performed.

In this case, the fourth cell string CS14 is the Type-A string, the third cell string CS13 sharing the second ground selection line GSL2 with the fourth cell string CS14 is the Type-B string, and the first and second cell strings CS11 and CS12 not sharing a ground selection line with the fourth cell string CS14 are the Type-C strings.

In FIGS. 9 to 11, when the Type-B string is in a state of being already programmed, the Type-B string may experience data damage due to hot electron injection in the process of performing the program operation of the Type-A string. Below, the above data damage which the Type-B string experiences will be described in detail with reference to FIGS. 12 and 13.

Referring to FIGS. 12 and 13 together, when the verify operation S130 is performed, a verify voltage may be applied to a selected word line, and a read voltage Vread may be applied to the first to fourth string selection lines SSL1 to SSL4, the first ground selection line GSL1, the upper unselected word lines UWL, and the lower unselected word lines LWL.

At a 0-th point in time t0, in the case of the first cell string CS11 being the Type-B string, when the read voltage Vread is applied to the first ground selection line GSL1, ground selection transistors may be turned on. In this case, a channel voltage of the first cell string CS11 may be maintained at a ground voltage GND. However, because memory cells of the first cell string CS11, which are connected to the upper unselected word lines UWL, are already programmed, the upper channel of the first cell string CS11 may have a positive voltage. For example, the voltage of the upper channel may be smaller than a word line voltage, for example, as much as a magnitude of a threshold voltage of the programmed memory cell.

In the case of the third and fourth cell strings CS13 and CS14 being the Type-C strings, the read voltage Vread may be applied to the third and fourth string selection lines SSL3 and SSL4 and the second ground selection line GSL2, and thus, the string selection transistors and the ground selection transistors may be turned on. Accordingly, channel voltages of the third and fourth cell strings CS13 and CS14 may be coupled to word lines and may be positive voltages. Below, a positive voltage which is generated through the coupling to the word lines is defined as a positive boost voltage.

As the recovery operation S140 is performed, the ground voltage GND may be applied to the first to fourth string selection lines SSL1 to SSL4, all the word lines, the first ground selection line GSL1, and the second ground selection line GSL2.

At a first point in time t1, a memory cell of the first cell string CS11 being the Type-B string, which is connected to the fifth word line WL5, is a memory cell already programmed. Accordingly, when the ground voltage GND is applied to the fifth word line WL5, the memory cell of the first cell string CS11 is in a turn-off state. That is, the upper channel and the lower channel of the first cell string CS11 may be electrically separated from each other.

When the ground voltage GND is applied to the upper unselected word lines UWL of the first cell string CS11 being the Type-B string, a voltage of the upper channel of the first cell string CS11 may be a negative voltage, which is defined as a negative boost voltage. The lower channel of the first cell string CS11 being the Type-B string may be coupled to the lower unselected word lines LWL and may have the ground voltage GND.

That is, an upper portion and a lower portion of the channel of the Type-B string may have different potentials, and a potential difference may be formed between the upper portion and the lower portion of the channel of the Type-B string.

In the case of the third and fourth cell strings CS13 and CS14 being the Type-C strings, channel voltages of the third and fourth cell strings CS13 and CS14 may be coupled to word lines and may be ground voltages GND.

When the initial precharge operation S110 is performed, the first to fourth string selection lines SSL1 to SSL4 and all the word lines may be maintained at the ground voltage GND, and a precharge voltage may be applied to the first ground selection line GSL1 and the second ground selection line GSL2. The precharge voltage may mean a voltage for performing the initial precharge operation, and a ground selection transistor to which the precharge voltage is applied may be turned on.

When the precharge voltage is applied to the first ground selection line GSL1 and the second ground selection line GSL2, the lower channel of the cell string may be precharged by carriers injected from a common source region.

At a second point in time t2, the initial boost-up voltage may be generated at the lower channels of cell strings being the Type-A, Type-B, and Type-C strings. The initial boost-up voltage may play a role in improving a voltage of a program-inhibited cell string together with the positive boost voltage in the process of performing the program voltage applying operation to be described later.

In the initial precharge operation S110, a bit line setup operation for selecting a bit line targeted for the program operation may be performed. When the bit line setup operation is performed, a string selection voltage may be applied to a string selection line of the Type-A string targeted for the program operation such that a string selection transistor is turned on.

When the program voltage applying operation S120 is performed, a turn-on voltage may be applied to the second string selection line SSL2, and the ground voltage GND may be applied to the first, third, and fourth string selection lines SSL1, SSL3, and SSL4. A program voltage may be applied to a selected word line, a pass voltage may be applied to unselected word lines, and a ground selection voltage may be applied to the first and second ground selection lines GSL1 and GSL2. The program voltage may be greater in magnitude than the pass voltage. Channel voltages of unselected cell strings may be coupled to word lines.

At a third point in time t3, in the case of the third and fourth cell strings CS13 and CS14 being the Type-C strings, channel voltages of the third and fourth cell strings CS13 and CS14 may be coupled to word lines, and thus, a positive boost voltage may be generated.

However, in the case of the first cell string CS11 being the Type-B string, a voltage of the lower channel of the first cell string CS11 may correspond to a voltage obtained by adding the initial boost-up voltage and the positive boost voltage, but a voltage of the upper channel of the first cell string CS11 may be still maintained at the negative voltage. That is, a potential difference between the upper channel and the lower channel may become greater.

When the potential difference increases (e.g., when the potential difference reaches a reference voltage VHCI for generating hot carriers), a hot carrier injection effect (HCI) in which hot carriers generated between the upper channel and the lower channel are injected into an information storage layer of the already programmed memory cell of the Type-B string may occur. That is, the data stored in the Type-B cell string may be damaged.

Below, some example embodiments of the program operation for preventing data stored in the already programmed memory cell of the Type-B string from being damaged when a threshold voltage of the already programmed memory cell of the Type-B string changes due to the hot carrier injection effect, or reducing or minimizing such damage, will be described with reference to FIGS. 14 to 20.

FIG. 14 is a diagram illustrating an example of a programming method (also referred to herein as a method of programming) according to some example embodiments of the present inventive concepts. It will be understood that the programming method shown in FIG. 14 may be implemented by a device according to any of the example embodiments (e.g., non-volatile memory device 100, non-volatile memory device 200, storage device 300, any combination thereof, or the like).

Referring to FIGS. 1, 2, and 14, in operation S210, the non-volatile memory device 100 may select cell strings (hereinafter referred to as “selected cell strings”) connected to a physical page targeted for the program operation.

For example, the non-volatile memory device 100 may select the first cell strings CS11 to CS31 of the first plane PLN1, the second cell strings CS12 to CS32 of the second plane PLN2, the third cell strings CS13 to CS33 of the third cell string CS13, or the fourth cell strings CS14 to CS34 of the fourth plane PLN4. For example, the non-volatile memory device 100 may select cell strings by applying the turn-on voltage to a string selection line associated with the physical page targeted for the program operation.

In operation S220, the non-volatile memory device 100 may select a word line (hereinafter referred to as a “selected word line”) connected to the physical page targeted for the program operation from among a plurality of word lines. For example, the non-volatile memory device 100 may not apply the program voltage to the remaining word lines among the plurality of word lines other than the selected word line.

In operation S230, the non-volatile memory device 100 may perform the program operation on the physical page connected to the selected word line. The program operation may include a program loop including a ground separate initial precharge operation.

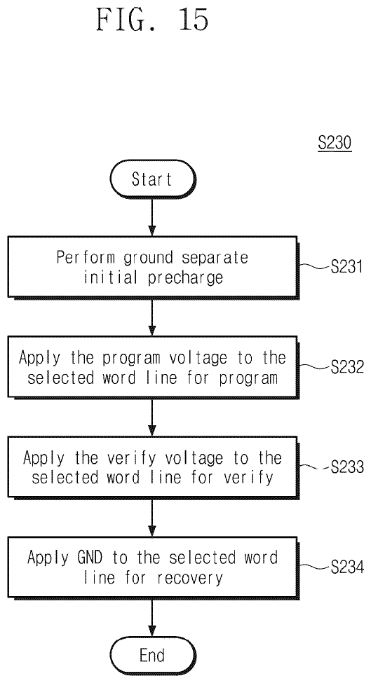

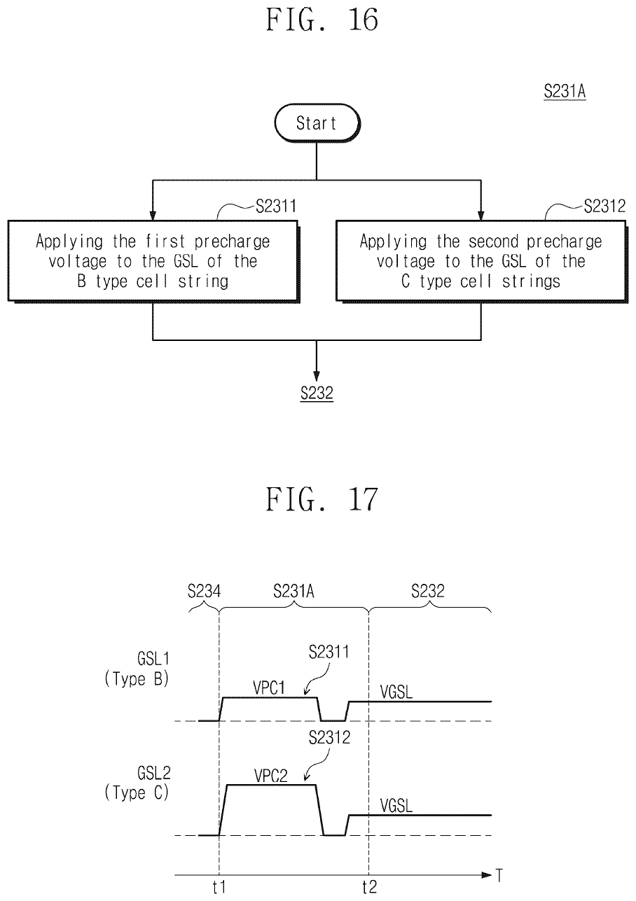

In some example embodiments, in the case of performing the ground separate initial precharge operation, the non-volatile memory device 100 may independently control voltages which are respectively applied to different ground selection lines. Some example embodiments of the ground separate initial precharge operation will be described in detail with reference to FIGS. 16 to 20.

As described with reference to FIGS. 2 and 3, the program operation may be sequentially performed with respect to physical pages of the same height, which are connected to the selected word line, along the second direction D2.

For example, after the program operation on the first cell strings CS11 to CS31 connected to the first string selection line SSL1 is completed, the non-volatile memory device 100 may select the second cell strings CS12 to CS32 connected to the second string selection line SSL2 as a program target.

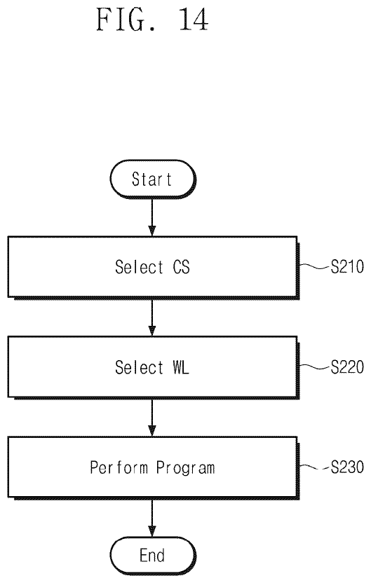

FIG. 15 is a diagram illustrating an example of a programming method of operation S230 of FIG. 14. It will be understood that the programming method shown in FIG. 15 may be implemented by a device according to any of the example embodiments (e.g., non-volatile memory device 100, non-volatile memory device 200, storage device 300, any combination thereof, or the like).

In operation S231, the non-volatile memory device 100 may perform the ground separate initial precharge operation. In the case of performing the ground separate initial precharge operation, the non-volatile memory device 100 may independently control voltages which are respectively applied to different ground selection lines.

In some example embodiments, the non-volatile memory device 100 may independently control a precharge voltage which is applied to a ground selection line connected to the Type-B string and a precharge voltage which is applied to a ground selection line connected to the Type-C string.

For example, referring to FIG. 9, the non-volatile memory device 100 may independently control a precharge voltage which is applied to the first ground selection line GSL1 connected to the first cell string CS11 being the Type-B string and a precharge voltage which is applied to the second ground selection line GSL2 connected to the third and fourth cell strings CS13 and CS14 being the Type-C strings. Some example embodiments of the ground separate initial precharge operation will be described with reference to FIGS. 16 to 27.

In operation S232, the program voltage applying operation in which a program voltage is applied to the selected word line may be performed; in operation S233, the verify operation in which a verify voltage is applied to the selected word line may be performed; in operation S234, the recovery operation in which a ground voltage is applied to word lines may be performed.

Operation S232 to operation S234 may be the same as operation S120 to operation S140 described with reference to FIG. 7.

FIG. 16 is a flowchart illustrating some example embodiments of a ground separate initial precharge operation of FIG. 14 according to some example embodiments of the present inventive concepts. FIG. 17 is a graph illustrating a ground separate initial precharge operation of FIG. 16 according to some example embodiments of the present inventive concepts. It will be understood that the ground separate initial precharge operation shown in FIGS. 16 and/or 17 may be implemented by a device according to any of the example embodiments (e.g., non-volatile memory device 100, non-volatile memory device 200, storage device 300, any combination thereof, or the like).

Referring to FIG. 16, in some example embodiments, a ground separate initial precharge operation S231A may include applying a first precharge voltage to a ground selection line connected to the Type-B cell string (S2311) and applying a second precharge voltage to a ground selection line connected to the Type-C cell string (S2312).

Referring to FIGS. 16 and 17 together, in operation S2311, the non-volatile memory device 100 may apply a first precharge voltage VPC1 to a ground selection line connected to the Type-B string. For example, in the situation of FIG. 9, in the case where the first cell string CS11 being the Type-B string is already programmed, the non-volatile memory device 100 may apply the first precharge voltage VPC1 to the first ground selection line GSL1 (e.g., operation S2311 may be performed concurrently with at least one memory cell connected to an upper unselected word line from among memory cells of the first cell string CS11 being in a state of being already programmed).

In operation S2312, the non-volatile memory device 100 may apply a second precharge voltage VPC2 to a ground selection line connected to the Type-C string. For example, in the situation of FIG. 9, the non-volatile memory device 100 may apply the second precharge voltage VPC2 to the second ground selection line GSL2 connected to the third and fourth cell strings CS13 and CS14 being the Type-C strings.

In some example embodiments, the magnitude of the first precharge voltage VPC1 may be smaller than the magnitude of the second precharge voltage VPC2. For example, the magnitude of the first precharge voltage VPC1 may be small enough not to turn on a first ground selection transistor connected to a first ground selection line.

Accordingly, the initial boost-up voltage formed at the lower channel of the cell string connected to the first ground selection line GSL1 to which the first precharge voltage VPC1 is applied may be smaller than the initial boost-up voltage formed at the lower channel of the cell string connected to the second ground selection line GSL2 to which the second precharge voltage VPC2 is applied.

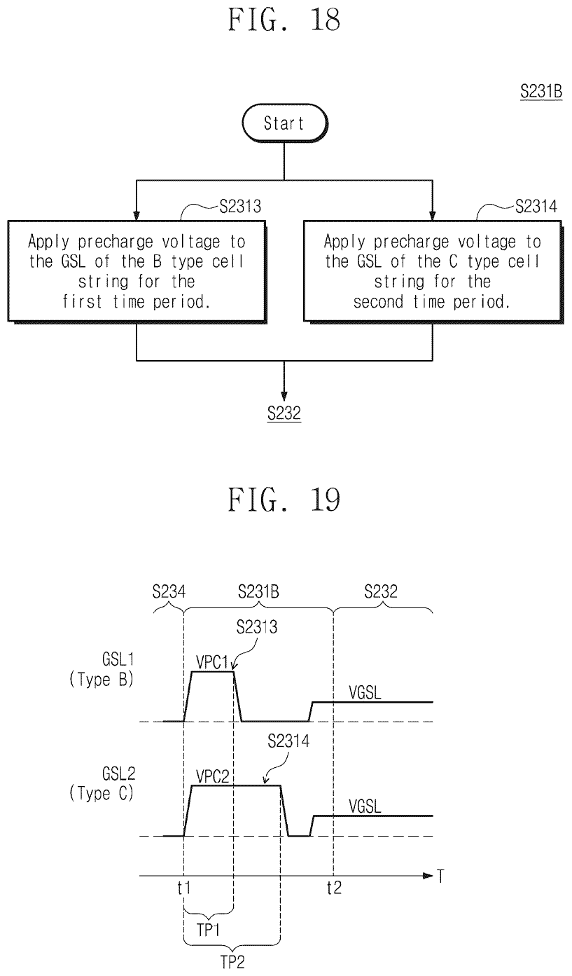

FIG. 18 is a flowchart illustrating some example embodiments of a ground separate initial precharge of FIG. 14 according to some example embodiments of the present inventive concepts. FIG. 19 is a graph illustrating a ground separate initial precharge operation of FIG. 18 according to some example embodiments of the present inventive concepts. It will be understood that the ground separate initial precharge operation shown in FIGS. 18 and/or 19 may be implemented by a device according to any of the example embodiments (e.g., non-volatile memory device 100, non-volatile memory device 200, storage device 300, any combination thereof, or the like).

Referring to FIG. 18, in some example embodiments, a ground separate initial precharge operation S231B may include applying a precharge voltage to a ground selection line connected to the Type-B cell string for a first time period (S2313) and applying a precharge voltage to a ground selection line connected to the Type-C cell string for a second time period (S2314). The first time period may be different from the second time period.

The precharge voltages applied in operation S2313 and operation S2314 may have the same magnitude. However, the present inventive concepts are not limited thereto. For example, precharge voltages of different magnitudes may be respectively applied to ground selection lines as described with reference to FIGS. 16 and 17.

Referring to FIGS. 18 and 19 together, in operation S2313, the non-volatile memory device 100 may apply a precharge voltage VPC to a ground selection line connected to the Type-B string for a first time period TP1. For example, in the situation of FIG. 9, in the case where the first cell string CS11 being the Type-B string is already programmed, the non-volatile memory device 100 may apply the precharge voltage VPC to the first ground selection line GSL1 for the first time period TP1 (e.g., may apply the precharge voltage VPC to the first ground selection line GSL1 for the first time period TP1 concurrently with at least one memory cell connected to an upper unselected word line from among memory cells of the first cell string being CS11 in a state of being already programmed).

In operation S2314, the non-volatile memory device 100 may apply the precharge voltage VPC to a ground selection line connected to the Type-C string for a second time period TP2. For example, in the situation of FIG. 9, the non-volatile memory device 100 may apply the precharge voltage VPC to the second ground selection line GSL2 connected to the third and fourth cell strings CS13 and CS14 being the Type-C strings for the second time period TP2.

In some example embodiments, the length of the first time period TP1 may be smaller than the length of the second time period TP2. For example, the second time period TP2 may include the first time period TP1. Accordingly, the initial boost-up voltage formed at the lower channel of the cell string connected to the first ground selection line GSL1 to which the precharge voltage VPC is applied for the first time period TP1 may be smaller than the initial boost-up voltage formed at the lower channel of the cell string connected to the second ground selection line GSL2 to which the precharge voltage VPC is applied for the second time period TP2.

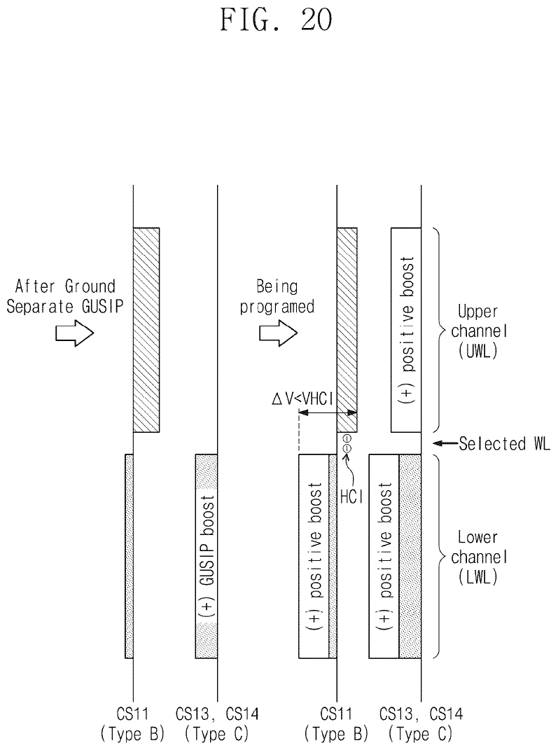

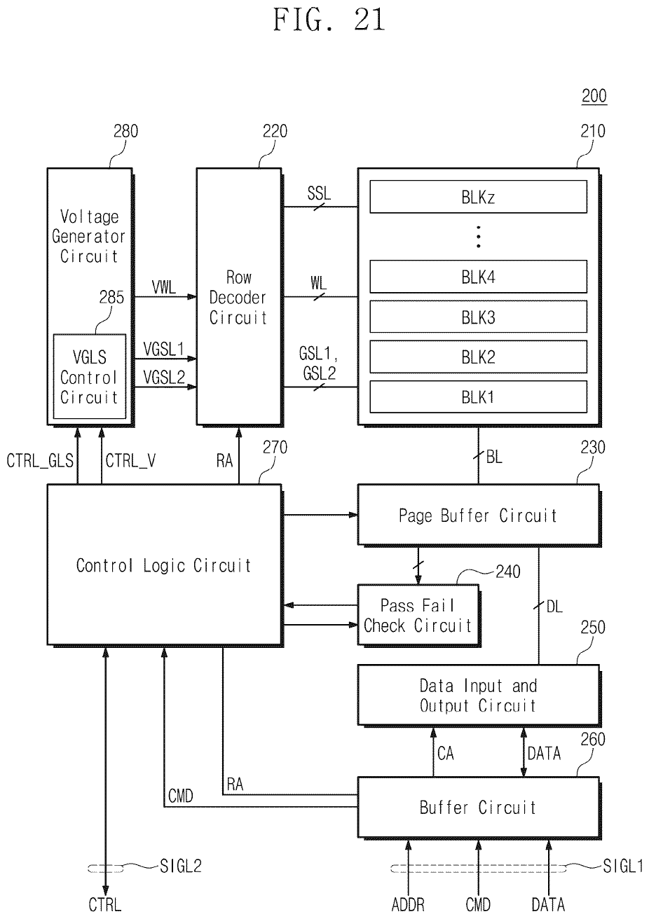

FIG. 20 is a diagram illustrating how a hot carrier injection effect is prevented, or reduced or minimized, based on a ground separate initial precharge operation being performed according to some example embodiments of the present inventive concepts. It will be understood that the operation shown in FIG. 20 may be implemented by a device according to any of the example embodiments (e.g., non-volatile memory device 100, non-volatile memory device 200, storage device 300, any combination thereof, or the like).

Referring to FIG. 20, in some example embodiments of the present inventive concepts, when the ground separate initial precharge operation is performed, the initial boost-up voltage formed at the lower channel of the Type-B string may be smaller than the initial boost-up voltage formed at the lower channel of the Type-C string. For example, the initial boost-up voltage formed at the lower channel of the first cell string CS11 being the Type-B string may be smaller than the initial boost-up voltage formed at the lower channel of each of the third and fourth cell strings CS13 and CS14 being the Type-C strings.

Afterwards, when the program voltage applying operation is performed, the channel of the Type-B string may be coupled to word lines, and thus, a positive boost-up voltage may be added thereto. However, a potential difference between the upper channel and the lower channel of the Type-B string may be smaller than that described with reference to FIG. 13. For example, the potential difference between the upper channel and the lower channel of the Type-B string may be smaller than the reference voltage VHCI for generating hot carriers. Accordingly, in the process of executing the program loop, the hot carrier injection effect may be reduced or minimized or prevented. This may mean that data of the already programmed memory cell of the Type-B string are prevented from being damaged, or such damage may be reduced or minimized. As a result, the programming performance, and thus memory storage performance and/or reliability, of a non-volatile memory device performing a program operation that further includes performing the ground separate initial precharge operation according to some example embodiments. Accordingly, the functionality of the non-volatile memory device may be improved.

FIG. 21 is a block diagram illustrating a non-volatile memory device according to some example embodiments of the present inventive concepts. Referring to FIG. 21, a non-volatile memory device 200 may include a memory cell array 210, a row decoder circuit 220, a page buffer circuit 230, a pass fail check circuit 240, a data input and output circuit 250, a buffer circuit 260, a control logic circuit 270, and a voltage generator circuit 280.

The memory cell array 210, the row decoder circuit 220, the page buffer circuit 230, the pass fail check circuit 240, the data input and output circuit 250, and the buffer circuit 260 may be the same or substantially the same as those described with reference to FIG. 1. Below, a difference will be mainly described.

The voltage generator circuit 280 may include a ground selection voltage control circuit 285. The ground selection voltage control circuit 285 may be configured to receive a ground selection voltage control signal CTRL_GSL from the control logic circuit 270. When the program operation is performed, the ground selection voltage control circuit 285 may be configured to control ground selection voltages VGSL1 and VGSL2 to be applied to the ground selection lines GSL1 and GSL2 based on the ground selection voltage control signal CTRL_GSL.

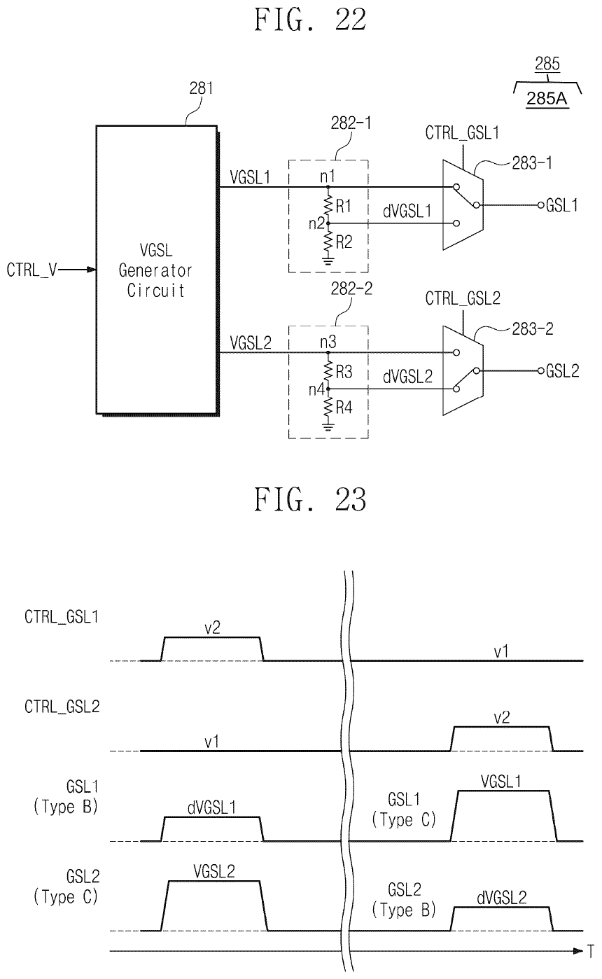

In some example embodiments, when the ground separate initial precharge operation is performed, the ground selection voltage control circuit 285 may be configured to independently control precharge voltages which are respectively applied to ground selection lines. When the program operation is performed, the non-volatile memory device 200 may be configured to perform the ground separate initial precharge operation described with reference to FIGS. 14 to 20 through the ground selection voltage control circuit 285. Below, a configuration and an operation of the ground selection voltage control circuit 285 will be described in detail with reference to FIGS. 22 and 23.

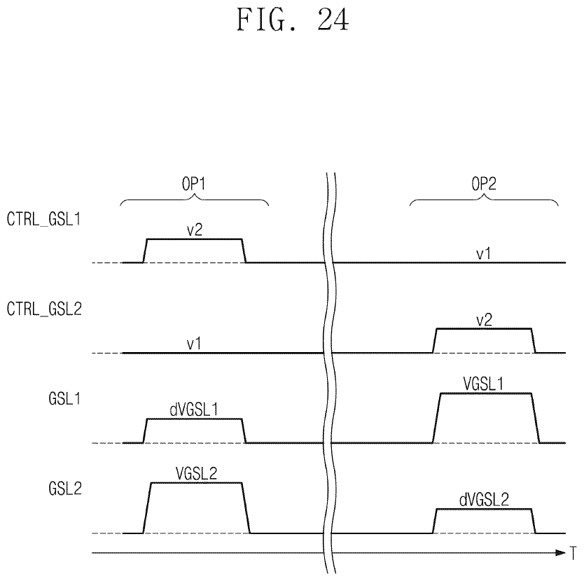

FIG. 22 is a diagram illustrating an example of a ground selection voltage control circuit of FIG. 21 according to some example embodiments of the present inventive concepts. FIG. 23 is a diagram for describing an example of an operation method of a ground selection voltage control circuit of FIG. 22 according to some example embodiments of the present inventive concepts. FIG. 24 is a diagram for describing an example of an operation method of a ground selection voltage control circuit of FIG. 22 according to some example embodiments of the present inventive concepts.

Referring to FIGS. 21 and 22, in some example embodiments, a ground selection voltage control circuit 285A, which may be included in and/or implemented by the ground selection voltage control circuit 285 in FIG. 21, may be configured to apply ground selection voltages of different magnitudes to ground selection lines, respectively, when the ground separate initial precharge operation is performed.

The ground selection voltage control circuit 285A may include a ground selection voltage generator circuit 281, a first voltage divider circuit 282-1, a first switch circuit 283-1, a second voltage divider circuit 282-2, and a second switch circuit 283-2.

The ground selection voltage generator circuit 281 may be configured to generate a ground selection voltage based on the voltage control signal CTRL_V from the control logic circuit 270. The ground selection voltage generator circuit 281 may be configured to adjust the magnitude of each of a plurality of ground selection voltages corresponding to a plurality of ground selection lines based on a ground selection voltage control signal.

For example, the ground selection voltage control signal may include a first ground selection voltage control signal CTRL_GSL1 corresponding to the first ground selection line GSL1 and a second ground selection voltage control signal CTRL_GSL2 corresponding to the second ground selection line GSL2.

The ground selection voltage generator circuit 281 may be configured to generate a first ground selection voltage VGSL1 corresponding to the first ground selection line GSL1 and a second ground selection voltage VGSL2 corresponding to the second ground selection line GSL2. When the ground separate initial precharge operation is performed, the first ground selection voltage VGSL1 and the second ground selection voltage VGSL2 which are generated by the ground selection voltage generator circuit 281 may have the same magnitude.

The first voltage divider circuit 282-1 may be configured to adjust the magnitude of the first ground selection voltage VGSL1 to be applied to the first ground selection line GSL1.

The first voltage divider circuit 282-1 may include a first resistor R1 and a second resistor R2 connected in series. A first end of the first resistor R1 may be connected to a first node n1, a second end of the first resistor R1 and a first end of the second resistor R2 may be connected to a second node n2, and a second end of the second resistor R2 may be grounded. The first ground selection voltage VGSL1 may be applied to the first node n1.

The first switch circuit 283-1 may be configured to electrically connect the first ground selection line GSL1 selectively to one of the first node n1 or the second node n2 of the first voltage divider circuit 282-1 based on the first ground selection voltage control signal CTRL_GSL1.

For example, when the first ground selection voltage control signal CTRL_GSL1 has a first value, the first switch circuit 283-1 may electrically connect the first ground selection line GSL1 to the first node n1 of the first voltage divider circuit 282-1 such that the first ground selection voltage VGSL1 is output without modification.

For example, when the first ground selection voltage control signal CTRL_GSL1 has a second value, the first switch circuit 283-1 may electrically connect the first ground selection line GSL1 to the second node n2 of the first voltage divider circuit 282-1 such that a first divided ground selection voltage dVGSL1 is output. The magnitude of the first divided ground selection voltage dVGSL1 may be smaller than the magnitude of the first ground selection voltage VGSL1.

The second voltage divider circuit 282-2 may be configured to adjust the magnitude of the second ground selection voltage VGSL2 to be applied to the second ground selection line GSL2.

The second voltage divider circuit 282-2 may include a third resistor R3 and a fourth resistor R4 connected in series. A first end of the third resistor R3 may be connected to a third node n3, a second end of the third resistor R3 and a first end of the fourth resistor R4 may be connected to a fourth node n4, and a second end of the fourth resistor R4 may be grounded. The second ground selection voltage VGSL2 may be applied to the third node n3.

The second switch circuit 283-2 may be configured to electrically connect the second ground selection line GSL2 selectively to one of the third node n3 or the fourth node n4 of the second voltage divider circuit 282-2 based on the second ground selection voltage control signal CTRL_GSL2.

For example, when the second ground selection voltage control signal CTRL_GSL2 has the first value, the second switch circuit 283-2 may electrically connect the second ground selection line GSL2 to the third node n3 of the second voltage divider circuit 282-2 such that the second ground selection voltage VGSL2 is output without modification.

For example, when the second ground selection voltage control signal CTRL_GSL2 has the second value, the second switch circuit 283-2 may electrically connect the second ground selection line GSL2 to the fourth node n4 of the second voltage divider circuit 282-2 such that a second divided ground selection voltage dVGSL2 is output.

Referring to FIG. 23, in some example embodiments, when the ground separate initial precharge operation is performed, the control logic circuit 270 may control a ground selection voltage control signal based on a string type of a cell string connected to a ground selection line. For example, a value of each ground selection voltage control signal may be determined based on a string type of a cell string connected to a ground selection line.

For example, when the Type-B string is included in cell strings connected to the first ground selection line GSL1 and the Type-C string is included in cell strings connected to the second ground selection line GSL2, the first ground selection voltage control signal CTRL_GSL1 may have a second value v2, and the second ground selection voltage control signal CTRL_GSL2 may have a first value v1.

That is, the first switch circuit 283-1 may output the first divided ground selection voltage dVGSL1 to the first ground selection line GSL1, and the second switch circuit 283-2 may output the second ground selection voltage VGSL2 to the second ground selection line GSL2 without modification. In this case, the first divided ground selection voltage dVGSL1 may be the same as the first precharge voltage VPC1 of FIG. 17, and the second ground selection voltage VGSL2 may be the same as the second precharge voltage VPC2 of FIG. 17.

For example, when the Type-B string is included in the cell strings connected to the second ground selection line GSL2 and the Type-C string is included in the cell strings connected to the first ground selection line GSL1, the second ground selection voltage control signal CTRL_GSL2 may have the second value v2, and the first ground selection voltage control signal CTRL_GSL1 may have the first value v1.

Referring to FIG. 24, in some example embodiments, the control logic circuit 270 may control a ground selection voltage control signal based on a program operation period. For example, a value of each ground selection voltage control signal may be determined based on the program operation period. The program operation period may include a first operation period OP1 and a second operation period OP2.

Each of the first operation period OP1 and the second operation period OP2 may be a portion of a period where different ground separate initial precharge operations are performed. For example, the first operation period OP1 may be a portion of a period where the program operation on a cell string connected to the first ground selection line GSL1 is performed, and the second operation period OP2 may be a portion of a period where the program operation on a cell string connected to the second ground selection line GSL2 is performed.

For example, in the first operation period OP1, the first ground selection voltage control signal CTRL_GSL1 may have the second value v2, and the second ground selection voltage control signal CTRL_GSL2 may have the first value v1. That is, the first switch circuit 283-1 may output the first divided ground selection voltage dVGSL1 to the first ground selection line GSL1, and the second switch circuit 283-2 may output the second ground selection voltage VGSL2 to the second ground selection line GSL2 without modification.

For example, in the second operation period OP2, the first ground selection voltage control signal CTRL_GSL1 may have the first value v1, and the second ground selection voltage control signal CTRL_GSL2 may have the second value v2. That is, the first switch circuit 283-1 may output the first ground selection voltage VGSL1 to the first ground selection line GSL1 without modification, and the second switch circuit 283-2 may output the second divided ground selection voltage dVGSL2 to the second ground selection line GSL2.

The first ground selection voltage control signal CTRL_GSL1 and the second ground selection voltage control signal CTRL_GSL2 may have the first value v1 in the remaining operations other than the ground separate initial precharge operation. In other words, the first switch circuit 283-1 may output the first ground selection voltage VGSL1 to the first ground selection line GSL1 without modification, and the second switch circuit 283-2 may output the second ground selection voltage VGSL2 to the second ground selection line GSL2 without modification.

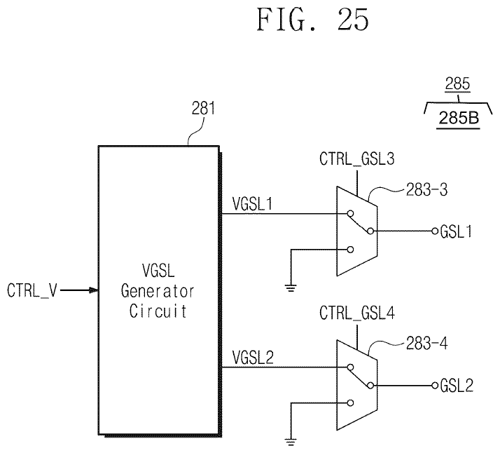

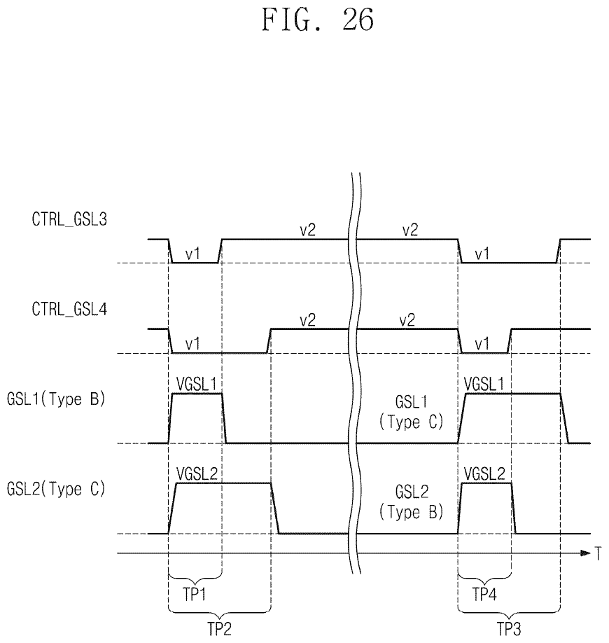

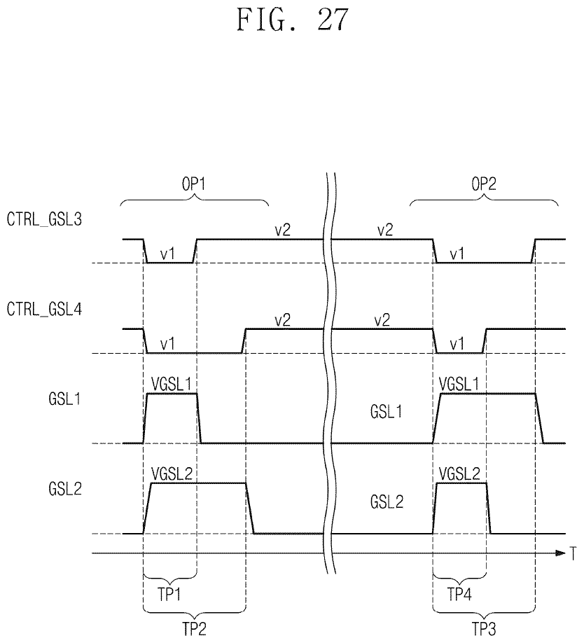

FIG. 25 is a diagram illustrating an example of a ground selection voltage control circuit of FIG. 21 according to some example embodiments of the present inventive concepts. FIG. 26 is a diagram for describing an example of an operation method of a ground selection voltage control circuit of FIG. 25 according to some example embodiments of the present inventive concepts. FIG. 27 is a diagram for describing an example of an operation method of a ground selection voltage control circuit of FIG. 25 according to some example embodiments of the present inventive concepts.

Referring to FIG. 25, in some example embodiments, when the ground separate initial precharge operation is performed, a ground selection voltage control circuit 285B, which may be included in and/or implemented by the ground selection voltage control circuit 285 in FIG. 21, may be configured to control a time during which a precharge voltage is applied to each ground selection line.

The ground selection voltage control circuit 285B may include the ground selection voltage generator circuit 281, a third switch circuit 283-3, and a fourth switch circuit 283-4.

The ground selection voltage generator circuit 281 may be configured to generate a ground selection voltage based on the voltage control signal CTRL_V from the control logic circuit 270. The ground selection voltage generator circuit 281 may be configured to generate a plurality of ground selection voltages corresponding to a plurality of ground selection lines. The ground selection voltage generator circuit 281 may be the same or substantially the same as that illustrated in FIG. 22.

For example, a ground selection voltage control signal may include a third ground selection voltage control signal CTRL_GSL3 corresponding to the first ground selection line GSL1 and a fourth ground selection voltage control signal CTRL_GSL4 corresponding to the second ground selection line GSL2.

The ground selection voltage generator circuit 281 may be configured to generate the first ground selection voltage VGSL1 corresponding to the first ground selection line GSL1 and the second ground selection voltage VGSL2 corresponding to the second ground selection line GSL2.

The third switch circuit 283-3 may be configured to selectively apply the first ground selection voltage VGSL1 or the ground voltage to the first ground selection line GSL1 based on the third ground selection voltage control signal CTRL_GSL3.

For example, when the third ground selection voltage control signal CTRL_GSL3 has the first value, the third switch circuit 283-3 may be configured to apply the first ground selection voltage VGSL1 to the first ground selection line GSL1. For example, when the third ground selection voltage control signal CTRL_GSL3 has the second value, the third switch circuit 283-3 may be configured to apply the ground voltage to the first ground selection line GSL1.

The fourth switch circuit 283-4 may be configured to selectively apply the second ground selection voltage VGSL2 or the ground voltage to the second ground selection line GSL2 based on the fourth ground selection voltage control signal CTRL_GSL4.

For example, when the fourth ground selection voltage control signal CTRL_GSL4 has the first value, the fourth switch circuit 283-4 may be configured to apply the second ground selection voltage VGSL2 to the second ground selection line GSL2. For example, when the fourth ground selection voltage control signal CTRL_GSL4 has the second value, the fourth switch circuit 283-4 may be configured to apply the ground voltage to the second ground selection line GSL2.

Referring to FIG. 26, in some example embodiments, when the ground separate initial precharge operation is performed, the control logic circuit 270 may control a ground selection voltage control signal based on a string type of a cell string connected to a ground selection line. For example, a value of each ground selection voltage control signal may be determined based on a string type of a cell string connected to a ground selection line.

For example, when the Type-B string is included in cell strings connected to the first ground selection line GSL1 and the Type-C string is included in cell strings connected to the second ground selection line GSL2, the third ground selection voltage control signal CTRL_GSL3 may have the first value v1 for the first time period TP1, and the fourth ground selection voltage control signal CTRL_GSL4 may have the first value v1 for the second time period TP2.

That is, the third switch circuit 283-3 may output the first ground selection voltage VGSL1 to the first ground selection line GSL1 for the first time period TP1, and the fourth switch circuit 283-4 may output the second ground selection voltage VGSL2 to the second ground selection line GSL2 for the second time period TP2.

In this case, the first ground selection voltage VGSL1 applied to the first ground selection line GSL1 during the first time period TP1 may be the same as the precharge voltage VPC (refer to FIG. 19) applied to the first ground selection line GSL1 for the first time period TP1, and the second ground selection voltage VGSL2 applied to the second ground selection line GSL2 for the second time period TP2 may be the same as the precharge voltage VPC (refer to FIG. 19) applied to the second ground selection line GSL2 for the second time period TP2.

For example, when the Type-B string is included in cell strings connected to the second ground selection line GSL2 and the Type-C string is included in cell strings connected to the first ground selection line GSL1, the third ground selection voltage control signal CTRL_GSL3 may have the first value v1 for a third time period TP3, and the fourth ground selection voltage control signal CTRL_GSL4 may have the first value v1 for a fourth time period TP4. The length of the fourth time period TP4 may be smaller than the length of the third time period TP3.

Referring to FIG. 27, in some example embodiments, the control logic circuit 270 may control a ground selection voltage control signal based on a program operation period. For example, a value of each ground selection voltage control signal may be determined based on the program operation period. The program operation period may include the first operation period OP1 and the second operation period OP2.

Each of the first operation period OP1 and the second operation period OP2 may be a portion of a period where the ground separate initial precharge operation is performed. For example, the first operation period OP1 may be a portion of a period where the program operation on a cell string connected to the first ground selection line GSL1 is performed, and the second operation period OP2 may be a portion of a period where the program operation on a cell string connected to the second ground selection line GSL2 is performed.

For example, in the first operation period OP1, the third ground selection voltage control signal CTRL_GSL3 may have the first value v1 for the first time period TP1, and the third ground selection voltage control signal CTRL_GSL4 may have the first value v1 for the second time period TP2.

For example, in the second operation period OP2, the third ground selection voltage control signal CTRL_GSL3 may have the first value v1 for the third time period TP3, and the fourth ground selection voltage control signal CTRL_GSL4 may have the second value v1 for the fourth time period TP4.

The third ground selection voltage control signal CTRL_GSL3 and the fourth ground selection voltage control signal CTRL_GSL4 may have the first value v1 in the remaining operations other than the ground separate initial precharge operation.

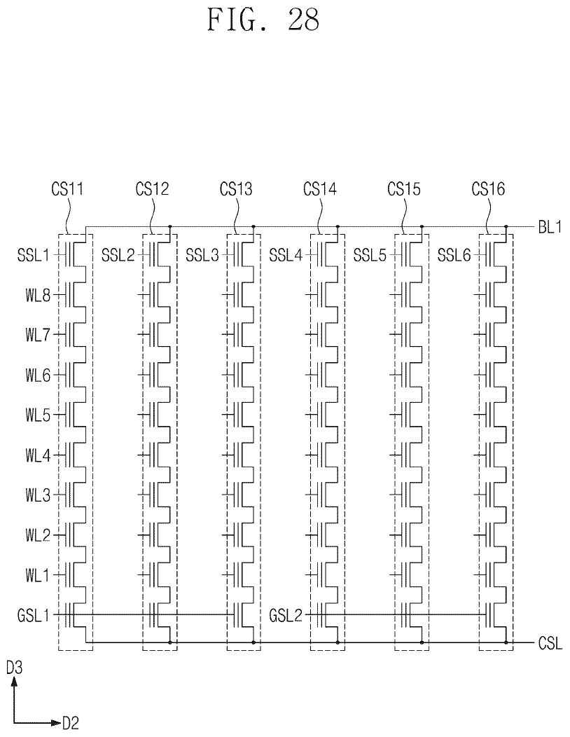

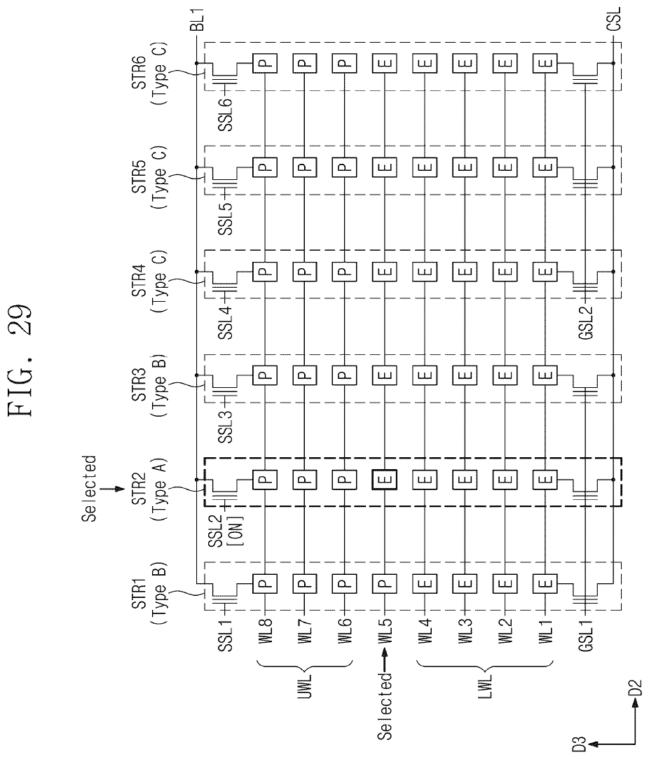

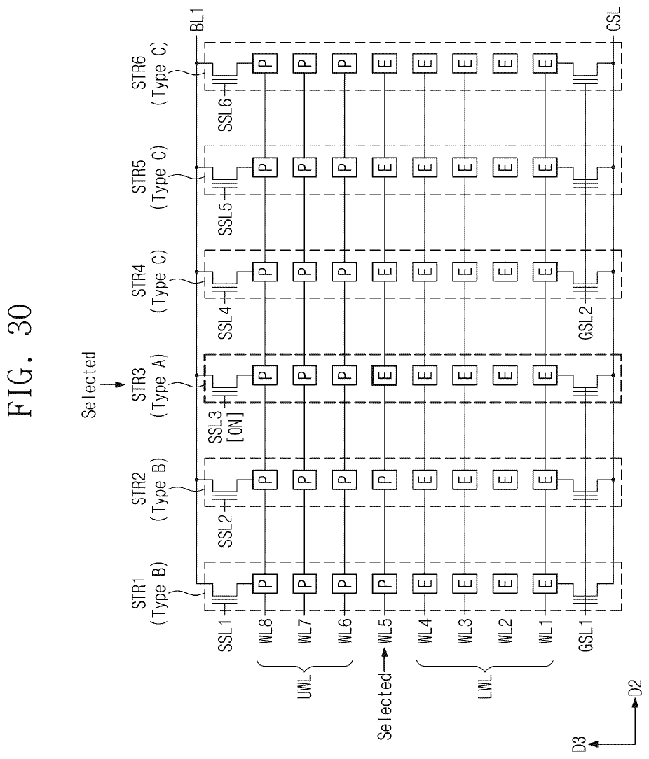

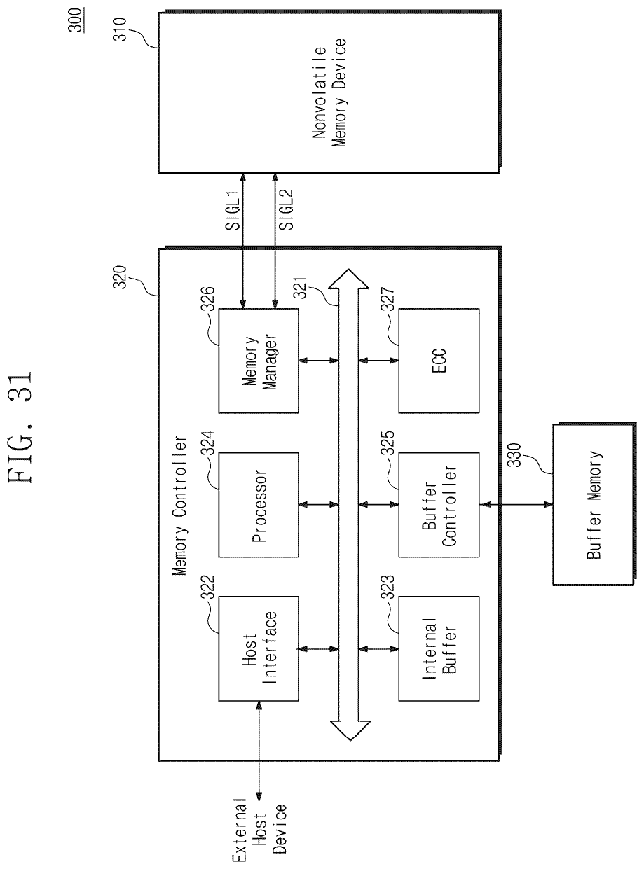

FIG. 28 is a diagram illustrating an example of a memory block according to some example embodiments of the present inventive concepts. FIGS. 29 and 30 illustrate an example in which memory cells connected to a fifth word line of FIG. 28 are programmed. Below, the description that is the same as the description given with reference to the example embodiments of FIGS. 28 to 30 will be omitted, and the description will be given based on a difference between embodiments.

In FIG. 28, first to sixth cell strings CS11 to CS16 connected to the first bit line BL1 of FIGS. 2 and 3 may be provided as an example. That is, components associated with the first bit line BL1 among the first to third bit lines BL1 to BL3 are only illustrated for convenience of description.

In some example embodiments, in a memory block of FIG. 1, at least three planes (i.e., cell strings) may be connected to the same ground selection line.

For example, first to third planes may be connected in common to the first ground selection line GSL1, and the first to third cell strings CS11 to CS13 may be simultaneously selected or may not be simultaneously selected based on the voltage applied to the first ground selection line GSL1.

For example, fourth to sixth planes may be connected in common to the second ground selection line GSL2, and the fourth to sixth cell strings CS14 to CS16 may be simultaneously selected or may not be simultaneously selected based on the voltage applied to the second ground selection line GSL2.

In some example embodiments, the first and second ground selection lines GSL1 and GSL2 may be electrically separated. The first ground selection voltage VGSL1 applied to the first ground selection line GSL1 and the second ground selection voltage VGSL2 applied to the second ground selection line GSL2 may be controlled by the voltage generator circuit 180 of FIG. 1 (or the ground selection voltage control circuit 285 of FIG. 21).

The first cell string CS11 of the first plane may be connected to the first string selection line SSL1, the second cell string CS12 of the second plane may be connected to the second string selection line SSL2, the third cell string CS13 of the third plane may be connected to the third string selection line SSL3, the fourth cell string CS14 of the fourth plane may be connected to the fourth string selection line SSL4, the fifth cell string CS15 of the fifth plane may be connected to the fifth string selection line SSL5, and the sixth cell string CS16 of the sixth plane may be connected to the sixth string selection line SSL6.

The first to sixth string selection lines SSL1 to SSL6 may be electrically separated. For example, the first to sixth cell strings CS11 to CS16 may be independently selected based on voltages applied to the first to sixth string selection lines SSL1 to SSL6 separated from each other.

The program operations on different physical pages disposed at the same height may be sequentially performed with respect to the first to sixth cell strings CS11 to CS16 along the second direction D2.

For example, the program operations on physical pages of the first to sixth cell strings CS11 to CS16, which are located at the same height, may be performed, and then, the program operations on physical pages of the first to sixth cell strings CS11 to CS16, which are immediately underlying, may be performed.

Referring to FIGS. 29 and 30, the program operations on memory cells of the first to sixth cell strings CS11 to CS15, which are connected to the fifth word line WL5, may be performed.

Referring to FIG. 29, after the program operation on the first cell string CS11 is completed, the program operation on the memory cell of the second cell string CS12, which is connected to the fifth word line WL5, may be performed.

In this case, the second cell string CS12 is the Type-A string, the first and third cell strings CS11 and CS13 sharing the first ground selection line GSL1 with the second cell string CS12 are the Type-B string, and the fourth to sixth cell strings CS14 to CS16 not sharing a ground selection line with the second cell string CS12 are the Type-C strings.

Referring to FIG. 30, after the program operation on the second cell string CS12 is completed, the program operation on the memory cell of the third cell string CS13, which is connected to the fifth word line WL5, may be performed.

In this case, the third cell string CS13 is the Type-A string, the first and second cell string CS11 and CS12 sharing the first ground selection line GSL1 with the third cell string CS13 are the Type-B string, and the fourth to sixth cell strings CS14 to CS16 not sharing a ground selection line with the third cell string CS13 are the Type-C strings.

In FIGS. 29 and 30, when the Type-B string is in a state of being already programmed, as described with reference to FIGS. 12 and 13, the Type-B string may experience data damage due to hot electron injection in the process of performing the program operation of the Type-A string. Accordingly, the programming method of the non-volatile memory device according to the present inventive concepts, which is described with reference to FIGS. 14 to 27, may also be identically applied to the above case.

FIG. 31 is a diagram illustrating a storage device according to some example embodiments of the present inventive concepts. Referring to FIG. 31, a storage device 300 may include a non-volatile memory device 310, a memory controller 320, and an external buffer 330, also referred to herein interchangeably as a buffer memory. The non-volatile memory device 310 may include a plurality of memory cells. Each of the plurality of memory cells may store two or more bits.

For example, the non-volatile memory device 310 may include at least one of various non-volatile memory devices such as a flash memory device, a phase-change memory device, a ferroelectric memory device, a magnetic memory device, and a resistive memory device. The non-volatile memory device 310 may include at least one of the non-volatile memory devices 100 and 200 described with reference to FIGS. 1 to 30.

The memory controller 320 may receive various requests for writing data in the non-volatile memory device 310 or reading data from the non-volatile memory device 310, from an external host device. The memory controller 320 may store (or buffer) user data communicated with the external host device in the external buffer 330 and may store meta data for managing the storage device 300 in the external buffer 330.

The memory controller 320 may access the non-volatile memory device 310 through the first signal lines SIGL1 and the second signal lines SIGL2. For example, the memory controller 320 may transmit a command and an address to the non-volatile memory device 310 through the first signal lines SIGL1. The memory controller 320 may exchange data with the non-volatile memory device 310 through the first signal lines SIGL1.

The memory controller 320 may transmit a first control signal to the non-volatile memory device 310 through the second signal lines SIGL2. The memory controller 320 may receive a second control signal from the non-volatile memory device 310 through the second signal lines SIGL2.

In some example embodiments, the memory controller 320 may be configured to control two or more non-volatile memory devices. The memory controller 320 may provide first signal lines and second signal lines for each of the two or more non-volatile memory devices.

As another example, the memory controller 320 may share the first signal lines with respect to the two or more non-volatile memory devices. The memory controller 320 may share some of the second signal lines with respect to the two or more non-volatile memory devices and may separately provide the others thereof.

The external buffer 330 may include a random access memory. For example, the external buffer 330 may include at least one of a dynamic random access memory, a phase-change random access memory, a ferroelectric random access memory, a magnetic random access memory, and a resistive random access memory.

The memory controller 320 may include a bus 321, a host interface 322, an internal buffer 323, a processor 324, a buffer controller 325, a memory manager 326, and an error correction code block 327.

The bus 321 may provide communication channels between the components of the memory controller 320. The host interface 322 may receive various requests from the external host device and may parse the received requests. The host interface 322 may store the parsed requests in the internal buffer 323.

The host interface 322 may transmit various responses to the external host device. The host interface 322 may exchange signals with the external host device in compliance with a given communication protocol. The internal buffer 323 may include a random access memory. For example, the internal buffer 323 may include a static random access memory or a dynamic random access memory.

The processor 324 may execute an operating system or firmware for driving the memory controller 320. The processor 324 may read the parsed requests stored in the internal buffer 323 and may generate addresses and commands for controlling the non-volatile memory device 310. The processor 324 may provide the generated commands and addresses to the memory manager 326.

The processor 324 may store various meta data for managing the storage device 300 in the internal buffer 323. The processor 324 may access the external buffer 330 through the buffer controller 325. The processor 324 may control the buffer controller 325 and the memory manager 326 such that the user data stored in the external buffer 330 are provided to the non-volatile memory device 310.

The processor 324 may control the host interface 322 and the buffer controller 325 such that the data stored in the external buffer 330 are provided to the external host device. The processor 324 may control the buffer controller 325 and the memory manager 326 such that the data received from the non-volatile memory device 310 are stored in the external buffer 330. The processor 324 may control the host interface 322 and the buffer controller 325 such that the data received from the external host device are stored in the external buffer 330.

Under control of the processor 324, the buffer controller 325 may write data in the external buffer 330 or may read data from the external buffer 330. The memory manager 326 may communicate with the non-volatile memory device 310 through the first signal lines SIGL1 and the second signal lines SIGL2 under control of the processor 324.

The memory manager 326 may access the non-volatile memory device 310 under control of the processor 324. For example, the memory manager 326 may access the non-volatile memory device 310 through the first signal lines SIGL1 and the second signal lines SIGL2. The memory manager 326 may communicate with the non-volatile memory device 310, based on a protocol defined in compliance with the standard or defined by a manufacturer.

The error correction code block 327 may perform error correction encoding with respect to data to be provided to the non-volatile memory device 310 by using the error correction code ECC. The error correction code block 327 may perform error correction decoding with respect to data received from the non-volatile memory device 310 by using the error correction code ECC.

In some example embodiments, the external buffer 330 and the buffer controller 325 may be omitted in the storage device 300. When the external buffer 330 and the buffer controller 325 are omitted, the functions which are described as being performed by the external buffer 330 and the buffer controller 325 may be performed by the internal buffer 323.

As described herein, any devices, systems, modules, portions, units, controllers, circuits, and/or portions thereof according to any of the example embodiments, and/or any portions thereof (including, without limitation, the non-volatile memory device 100, the memory cell array 110, the row decoder circuit 120, the page buffer circuit 130, the data input and output circuit 150, the buffer circuit 160, the control logic circuit 170, the voltage generator circuit 180, the non-volatile memory device 200, the memory cell array 210, the row decoder circuit 220, the page buffer circuit 230, the pass fail check circuit 240, the data input and output circuit 250, the buffer circuit 260, the control logic circuit 270, the voltage generator circuit 280, the ground selection voltage generator circuit 281, the ground selection voltage control circuit 285, the ground selection voltage control circuit 285A, the ground selection voltage control circuit 285B, the storage device 300, the non-volatile memory device 310, the memory controller 320, the host interface 322, the internal buffer 323, the processor 324, the buffer controller 325, the memory manager 326, the error correction code block 327, the external buffer 330, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

According to some example embodiments of the present inventive concepts, there is provided a programming method for preventing data from being damaged while a program operation is performed, or reducing or minimizing such damage, thereby improving the programming performance, and thus memory storage performance and/or reliability, of a non-volatile memory device performing a program operation that further includes performing the ground separate initial precharge operation according to some example embodiments and furthermore improving the functionality of the non-volatile memory device and any device including same (e.g., a storage device).

Also, according to some example embodiments of the present inventive concepts, there is provided a non-volatile memory device performing a program operation for preventing data from being damaged while the program operation is performed, or reducing or minimizing such damage, thereby improving the programming performance, and thus memory storage performance and/or reliability, of a non-volatile memory device performing a program operation that further includes performing the ground separate initial precharge operation according to some example embodiments and furthermore improving the functionality of the non-volatile memory device and any device including same (e.g., a storage device).

While the present inventive concepts have been described with reference to some example embodiments thereof, it will be apparent to those of ordinary skill in the art that various changes and modifications may be made thereto without departing from the spirit and scope of the present inventive concepts as set forth in the following claims.

What is claimed is:

1. A method of programming a non-volatile memory device, the non-volatile memory device including a first cell string and a second cell string connected to one bit line and sharing a first ground selection line, the non-volatile memory device further including a third cell string and a fourth cell string connected to the one bit line and sharing a second ground selection line, the method comprising:
performing a ground separate initial precharge operation in which a first voltage is applied to the first ground selection line and a second voltage is applied to the second ground selection line, based on the first cell string being selected as a selected cell string;
performing a program voltage applying operation in which a program voltage is applied to a word line selected as a selected word line from among a plurality of word lines;
performing a verify operation in which a verify voltage is applied to the selected word line; and
performing a recovery operation in which a recovery voltage is applied to the plurality of word lines connected to the first to fourth cell strings.

2. The method of claim 1, wherein the method is sequentially performed from an uppermost unselected word line that is closest to a string selection line from among the plurality of word lines to a lowermost word line among the plurality of word lines along a top-down direction.

3. The method of claim 2, wherein, the ground separate initial precharge operation is performed concurrently with at least one memory cell connected to an upper unselected word line from among memory cells of the first cell string being in a state of being already programmed.

4. The method of claim 3, wherein the first voltage is smaller in magnitude than the second voltage.

5. The method of claim 3, wherein
performing the ground separate initial precharge operation includes applying the first voltage to the first ground selection line for a first time period, and applying the second voltage to the second ground selection line for a second time period, and
the first time period is smaller than the second time period.

6. A method of programming a non-volatile memory device, the non-volatile memory device including a plurality of cell strings connected to a same bit line, the method comprising:
selecting one cell string of the plurality of cell strings as a selected cell string;
selecting one word line of a plurality of word lines connected to the selected cell string as a selected word line; and
performing a program operation on memory cells connected to the selected word line,
wherein the performing of the program operation includes
performing a ground separate initial precharge operation based on applying a first voltage to a first ground selection line connected to the selected cell string and applying a second voltage to a second ground selection line connected to an unselected cell string among the plurality of cell strings.

7. The method of claim 6, wherein the program operation is sequentially performed from an uppermost unselected word line that is closest to a string selection line from among the plurality of word lines to a lowermost word line among the plurality of word lines along a top-down direction.

8. The method of claim 7, wherein the ground separate initial precharge operation is performed concurrently with at least one memory cell connected to an upper unselected word line from among memory cells of the plurality of cell strings being in a programmed state.

9. The method of claim 6, wherein the performing of the program operation further includes:
performing a program voltage applying operation on the selected word line;
performing a verify operation in which a verify voltage is applied to the selected word line; and
performing a recovery operation on the plurality of word lines.

10. The method of claim 9, wherein the first voltage is smaller in magnitude than the second voltage.

11. The method of claim 9, wherein
performing the ground separate initial precharge operation includes applying the first voltage to the first ground selection line for a first time period, and applying the second voltage to the second ground selection line for a second time period, and
the first time period is smaller than the second time period.

12. The method of claim 9, wherein performing the ground separate initial precharge operation includes applying a same voltage to the first ground selection line and the second ground selection line in a state where memory cells of cell strings connected to the first ground selection line are not programmed.

13. A non-volatile memory device, comprising:
a plurality of memory blocks,
wherein each memory block of the plurality of memory blocks includes
a first cell string and a second cell string connected to a same bit line and sharing a first ground selection line, and
a third cell string and a fourth cell string connected to the same bit line and sharing a second ground selection line,
wherein the non-volatile memory device is configured to perform a precharge operation on a cell string of the first to fourth cell strings, the precharge operation including
independently controlling a first ground selection voltage applied to the first ground selection line and a second ground selection voltage applied to the second ground selection line.

14. The non-volatile memory device of claim 13, further comprising:
a control logic circuit configured to generate a ground selection voltage control signal; and
a ground selection voltage control circuit configured to control the first ground selection voltage and the second ground selection voltage based on the ground selection voltage control signal.

15. The non-volatile memory device of claim 14, wherein
the ground selection voltage control signal includes a first ground selection voltage control signal and a second ground selection voltage control signal,
the ground selection voltage control circuit is configured to
control a magnitude of the first ground selection voltage applied to the first ground selection line based on the first ground selection voltage control signal, and
control a magnitude of the second ground selection voltage applied to the second ground selection line based on the second ground selection voltage control signal, and
the magnitude of the first ground selection voltage is different from the magnitude of the second ground selection voltage.

16. The non-volatile memory device of claim 15, wherein the control logic circuit is configured to:
control the first ground selection voltage control signal based on a string type of a cell string connected to the first ground selection line; and
control the second ground selection voltage control signal based on a string type of a cell string connected to the second ground selection line.

17. The non-volatile memory device of claim 15, wherein the control logic circuit is configured to:
control the first and second ground selection voltage control signals based on a first operation period such that the magnitude of the first ground selection voltage is smaller than the magnitude of the second ground selection voltage; and
control the first and second ground selection voltage control signals based on a second operation period such that the magnitude of the second ground selection voltage is smaller than the magnitude of the first ground selection voltage,
wherein the first operation period is a portion of a period where a program operation on a cell string connected to the first ground selection line is performed, and
wherein the second operation period is a portion of a period where a program operation on a cell string connected to the second ground selection line is performed.

18. The non-volatile memory device of claim 14, wherein
the ground selection voltage control signal includes a first ground selection voltage control signal and a second ground selection voltage control signal,
the ground selection voltage control circuit is configured to
apply the first ground selection voltage to the first ground selection line for a first time period, based on the first ground selection voltage control signal, and
apply the second ground selection voltage to the second ground selection line for a second time period, based on the second ground selection voltage control signal, and
the first time period is different from the second time period.

19. The non-volatile memory device of claim 18, wherein the control logic circuit is configured to:
control the first ground selection voltage control signal based on a string type of a cell string connected to the first ground selection line; and
control the second ground selection voltage control signal based on a string type of a cell string connected to the second ground selection line.

20. The non-volatile memory device of claim 18, wherein the control logic circuit is configured to:
control the first and second ground selection voltage control signals based on a first operation period such that the first time period is smaller than the second time period; and
control the first and second ground selection voltage control signals based on a second operation period such that the first time period is greater than the second time period,
wherein the first operation period is a portion of a period where a program operation on a cell string connected to the first ground selection line is performed, and
wherein the second operation period is a portion of a period where a program operation on a cell string connected to the second ground selection line is performed.
